(19) United States
(12) Patent Application Publication
(10) Pub. No.: US 2008/0090396 A1
(43) Pub. Date: Apr. 17, 2008

(54) LIGHT EXPOSURE APPARATUS AND METHOD FOR MAKING SEMICONDUCTOR DEVICE FORMED USING THE SAME

(75) Inventor: Hideto OHNUMA, Atsugi (JP)

Correspondence Address: NIXON PEABODY, LLP, 401 9TH STREET, NW, SUITE 900, WASHINGTON, DC, 20004-2128, US

(73) Assignee: SEMICONDUCTOR ENERGY LABORATORY CO., LTD., Atsugi-shi (JP)

(21) Appl. No.: 11/867,363

(22) Filed: Oct. 4, 2007

(30) Foreign Application Priority Data
Oct. 6, 2006 (JP) 2006-275663

(51) Int. Cl. H01L 21/283; G03C 5/00; G21K 5/00

(52) U.S. Cl. 438/585; 250/492.22; 430/311; 257/E21.159

(57) ABSTRACT

An object of the present invention is to reduce variation in light exposure on an irradiation surface through a mask when the surface is exposed to laser light emitted from a laser source, whereby improving the throughput in light exposure of a substrate. Light exposure is performed using a solid-state laser which emits pulsed laser light having a repetition rate of 1 MHz or more as a light source for light exposure in a photolithography process. As a result, variation in light exposure on the surface irradiated with the laser light can be suppressed.

### BACKGROUND OF THE INVENTION

1. Field of the Invention

The present invention relates to light exposure apparatuses by which light exposure is performed in a photolithography process. In particular, the present invention relates to a light exposure apparatus for scanning an irradiation surface with pulsed laser light (hereinafter, also referred to as a pulsed laser beam) which is processed into a linear shape using an optical system, thereby exposing the irradiation surface to light through a photomask. Furthermore, the present invention relates to semiconductor devices which are formed using the light exposure apparatus.

2. Description of the Related Art

In recent years, various kinds of electronic devices have spread and various products have been on sale. Among electronic devices, semiconductor devices including a plurality of transistors have greatly advanced in a fine-resolution technology in a photolithography process (light exposure process, hereinafter) and further development has been proceeding.

In a process for making a semiconductor device, a light exposure technique for forming minute patterns such as wiring and contact holes is essential to perform precise microfabrication. In a light exposure process, the following steps are taken: a photoresist is applied to form a film over a substrate; the photoresist film is exposed to light through a photomask (also simply referred to as a mask, hereinafter) having a predetermined pattern; and then the photoresist film is developed with a developing solution, so that a desired pattern of an integrated circuit is formed.

In the light exposure process, the photoresist film is exposed to laser light which is emitted from a light source (also referred to as a laser oscillator). The light source for performing the light exposure process is classified roughly into two types, according to a method for oscillating laser light: pulsed oscillation and continuous wave oscillation. As an example of a laser oscillator, a pulsed laser oscillator (also referred to as a pulsed laser), e.g. an excimer laser, can be given. An excimer laser used for a light exposure apparatus has a repetition rate of 2 to 4 kHz. It is technically difficult to have a repetition rate higher than this (Patent Document 1: Japanese Published Patent Application No. 2005-142306). As another example of a laser oscillator, a continuous-wave laser oscillator (also referred to as a CW laser), e.g. an Ar laser or a YVO₄ laser, can be given.

There are some methods in laser light exposure by a laser exposure apparatus: forming laser light into a linear shape by an optical system at an irradiation surface and moving the laser light relatively to the surface; and forming laser light into a planar shape by an optical system and exposing a surface to the laser light at one time.

Note that “linear” here denotes a rectangle or ellipse with a high aspect ratio (e.g. an aspect ratio of 10 or more, preferably, 100 to 10000), not a “line” in the truest sense.

Whether the laser light from the laser source used for a laser source of a light exposure apparatus is processed into a linear shape or into a planar shape, there is a variation in the intensity distribution of the laser light (also referred to as an “energy profile”) and the variation of light exposure amount becomes noticeable on an irradiation surface. In order to counter such a problem, in Patent Document 2 (Japanese Published Patent Application No. 2000-216086), a structure is disclosed in which a doze control is provided in a light exposure apparatus which emits linear-shaped laser light so that variation of line width can be suppressed which is caused by variation in light exposure amount on an irradiation surface.

In particular, in pulsed lasers and CW lasers which are used for laser sources, a problem of variation becomes more noticeable in the former.

### SUMMARY OF THE INVENTION

The intensity distribution (also referred to as an “energy profile”) of laser light from a laser source is Gaussian: the intensity of the laser light tends to decrease towards the end. Therefore, the energy becomes weaker towards the end of a beam spot, which leads to low throughput in a light exposure process. Similarly, even if the intensity distribution of laser light is processed to have a top-flat shape with an optical system which is provided in a path from a laser source to a photomask in a light exposure apparatus, a problem of variation in the intensity distribution of laser light, in which the intensity decreases towards the end, can be left.

A CW laser, which is used for a laser source of a light exposure apparatus in order to reduce the variation in the intensity distribution, has low output, and the throughput is not good enough to expose a resist to light and perform development. When an Ar laser or a YAG laser is used, which perform continuous oscillation, it is difficult to acquire a high output: as for the Ar ion laser, the output of a laser oscillator on the market is 2 W or smaller at a wavelength of 363.8 nm. Therefore, in manufacturing semiconductor devices in large quantities, improvement in throughput of a light exposure process can be a challenge.

With a light exposure apparatus in which a large glass substrate is exposed to light by a scanning method using a pulsed excimer laser, it is difficult to achieve both improvement in throughput and uniformity of intensity distribution since the repetition rate is too low for a large glass substrate which forms a flat panel display of the like. When a large glass substrate is exposed to light by a scanning method, an excimer laser is not sufficient for a laser source of a light exposure apparatus since the light source is required to have a high output, high repetition rate, and stability in oscillation.

An object of the present invention is to provide a light exposure apparatus in which variation in light exposure is reduced when an irradiation surface is exposed to the laser light from a laser source through a mask to improve the throughput in light exposure of a substrate, and a method for making a semiconductor device formed using the light exposure apparatus.

One feature of the present invention is that light exposure is performed using a solid-state laser which emits pulsed laser Light having a repetition rate of 1 MHz or more as a light source for exposure in a photolithography process.

An aspect of the light exposure apparatus of the present invention is a light exposure apparatus in which pulsed laser light is used as a laser source in a light exposure process, a solid-state laser is used as the laser source in the light exposure apparatus for exposing an irradiation surface to the laser light through a mask, and the repetition rate of the laser light is 1 MHz or more.

Another aspect of the light exposure apparatus of the present invention is a light exposure apparatus in which pulsed laser light is used as a laser source in a light exposure process, a solid-state laser is used as the laser source in the light exposure apparatus for exposing an irradiation surface to the laser light through a mask, and the repetition rate of the laser light is 5 MHz or more.

Another aspect of the light exposure apparatus of the present invention is a light exposure apparatus in which pulsed laser light is used as a laser source in a light exposure process, a solid-state laser is used as the laser source in the light exposure apparatus for exposing an irradiation surface to the laser light through a mask, and the repetition rate of the laser light is 50 MHz or more.

Another aspect of the light exposure apparatus of the present invention is a light exposure apparatus in which pulsed laser light is used as a laser source in a light exposure process, a solid-state laser is used as the laser source in the light exposure apparatus for exposing an irradiation surface to the laser light through a mask, and the repetition rate of the laser light is 80 MHz or more.

The mask in the light exposure apparatus of the present invention may be a photomask or a reticle on which a pattern is formed on a transparent substrate by a light-shielding film.

The mask in the light exposure apparatus of the present invention may be a hologram or a computer-generated hologram.

The pulse width of the laser light in the light exposure apparatus of the present invention may be 1/100 or smaller one cycle width of the laser light.

The pulse width of the laser light in the light exposure apparatus of the present invention may be 1/200 or smaller of one cycle width of the laser light.

The pulse width of the laser light in the light exposure apparatus of the present invention may be 1/500 or smaller of one cycle width of the laser light.

The irradiation surface may be scanned with the laser light of the light exposure apparatus of the present invention as the laser light moves relatively to the surface.

The irradiation surface in the light exposure apparatus of the present invention may be a surface of a resist or photosensitive resin such as photosensitive polyimide or photosensitive acrylic applied over a substrate.

The laser light in the light exposure apparatus of the present invention may have a linear shape.

An aspect of a method for making the semiconductor device of the present invention is that a resist film over a substrate is exposed to pulsed laser light to perform a light exposure process in making the semiconductor device, wherein a solid-state laser is used as a laser source of the laser light, and the laser light has a repetition rate of 1 MHz or higher.

Another aspect of a method for making the semiconductor device of the present invention is that a resist film over a substrate is exposed to pulsed laser light to perform a light exposure process in making the semiconductor device, wherein a solid-state laser is used as a laser source of the laser light, and the laser light has a repetition rate of 5 MHz or higher.

Another aspect of a method for making the semiconductor device of the present invention is that a resist film over a substrate is exposed to pulsed laser light to perform a light exposure process in making the semiconductor device, wherein a solid-state laser is used as a laser source of the laser light, and the laser light has a repetition rate of 50 MHz or higher.

Another aspect of a method for making the semiconductor device of the present invention is that a resist film over a substrate is exposed to pulsed laser light to perform a light exposure process in making the semiconductor device, wherein a solid-state laser is used as a laser source of the laser tight, and the laser light has a repetition rate of 80 MHz or higher.

In the light exposure process in the present invention, a photomask or a reticle on which a pattern is formed on a transparent substrate by a light-shielding film may be used as a mask.

In the light exposure process in the present invention, a hologram or the computer-generated hologram may be used as a mask.

The pulse width of the laser light of the present invention may be 1/100 or smaller one cycle width of the laser light.

The pulse width of the laser light of the present invention may be 1/200 or smaller of one cycle width of the laser light.

The pulse width of the laser light of the present invention may be 1/500 or smaller of one cycle width of the laser light.

In the present invention, the movement rate is 0.1 μm or smaller every pulse, and the maximum value of a scanning speed is 5 cm/sec or more.

In the present invention, the movement rate is 0.01 μm or smaller every pulse, and the maximum value of a scanning speed is 5 cm/sec or more.

In the present invention, an overlap percentage of the laser light between pulses may be 99.9% or more, and the maximum value of a scanning speed may be 5 cm/sec or more.

In the present invention, an overlap percentage of the laser light between pulses may be 99.99% or more, and the maximum value of a scanning speed may be 5 cm/sec or more.

In the present invention, an overlap percentage of the laser light between pulses may be 99.999% or more, and the maximum value of a scanning speed may be 5 cm/sec or more.

In the present invention, the irradiation surface may be scanned with the laser light as the laser light moves relatively to the surface.

In the present invention, the laser light may have a linear shape.

With the light exposure apparatus of the present invention, variation in laser light exposure on an irradiation surface can be suppressed. Accordingly, variation in line width such as that of wiring can be suppressed in the semiconductor devices, so that the defect rate of semiconductor devices can be suppressed. Therefore, a yield in semiconductor devices can be improved and semiconductor devices with reduced variation can be made.

In addition, in the light exposure apparatus of the present invention, improvement in throughput in the light exposure process of the semiconductor device can be expected since the speed of scanning a substrate can be increased. Therefore, takt time can be reduced considerably in a method for making the semiconductor devices each having one substrate.

### BRIEF DESCRIPTION OF THE DRAWINGS

In the accompanying drawings:

FIG. 1 is a diagram illustrating an embodiment mode of the present invention.

FIGS. 2A to 2C are diagrams illustrating an embodiment mode of the present invention.

FIG. 3 is a diagram illustrating an embodiment mode of the present invention.

FIG. 4 is a diagram illustrating an embodiment mode of the present invention.

FIG. 5 is a diagram illustrating an embodiment mode of the present invention

FIG. 6 is a diagram illustrating an embodiment mode of the present invention FIGS. 7A and 7B are diagrams each illustrating an embodiment mode of the present invention.

FIGS. 8A and 8B are diagrams each illustrating an embodiment mode of the present invention.

FIGS. 9A and 9B are diagrams each illustrating an embodiment mode of the present invention.

FIG. 10 is a diagram illustrating a method for making a semiconductor device according to the present invention.

FIG. 11 is a diagram illustrating a method for making a semiconductor device according to the present invention.

FIG. 12 is a diagram illustrating a method for making a semiconductor device according to the present invention.

FIG. 13 is a diagram illustrating a method for making a semiconductor device according to the present invention.

FIG. 14 is a diagram illustrating a method for making a semiconductor device according to the present invention.

FIG. 15 is a diagram illustrating a method for making a semiconductor device according to the present invention.

FIG. 16 is a diagram illustrating a method for making a semiconductor device according to the present invention.

FIG. 17 is a diagram illustrating a method for making a semiconductor device according to the present invention.

FIG. 18 is a diagram illustrating a method for making a semiconductor device according to the present invention.

FIG. 19 is a diagram illustrating a method for making a semiconductor device according to the present invention.

FIGS. 20A and 20B are diagrams of electronic devices including semiconductor devices formed according to the present invention.

FIGS. 21A to 21D are diagrams of electronic devices including semiconductor devices formed according to the present invention.

### DETAILED DESCRIPTION OF THE INVENTION

### Embodiment Modes

Embodiment modes of the present invention are described hereinafter. Note that the present invention can be performed in many different modes and it is easily understood by those skilled in the art that the modes and details disclosed herein can be modified in various ways without departing from the spirit and the scope of the present invention. Therefore, the present invention should not be interpreted as being limited to the description of the embodiment modes to be given below.

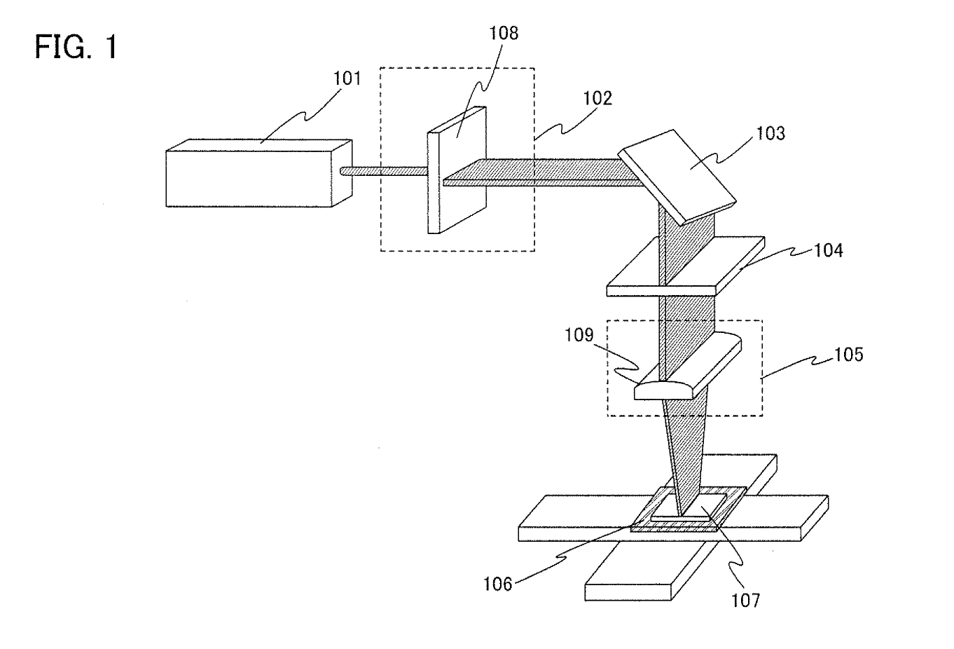

An example of a light exposure apparatus of the present invention is shown in FIG. 1. The light exposure apparatus includes a laser source 101, a beam optical system 102, a mirror 103, a photomask 104, a projection optical system 105, a substrate stage 106, and a substrate 107. The beam optical system 102 is provided with a lens 108, which shapes and evens up the intensity distribution of the laser light. The lens 108 provided in the beam optical system 102 can include a plurality of lenses among an array lens, a collimation lens, a field lens, and the like. The projection optical system 105 is provided with a projection lens 109. As the projection lens 109 provided in the projection optical system 105, it is preferable to use a convex cylindrical lens, but a convex spherical lens can also be used. The mirror 103 may be provided depending on an arrangement of an optical system of the light exposure apparatus. The substrate stage 106 is moved in an x-direction and a y-direction, so that an irradiation surface on the substrate 107 is exposed to light. The light exposure apparatus includes a photomask stage (not shown in the diagram) on which the photomask 104 is scanned in synchronization with the scanning on the substrate stage 106. The irradiation surface on the substrate may be scanned with laser light which is processed into a linear shape. That is, it is acceptable as long as the irradiation surface on the substrate is relatively scanned with laser light, and the substrate stage and the laser light may be controlled together.

In the present invention, a solid-state laser of pulsed oscillation with a repetition rate of 1 MHz or more is used as the laser source 101. In the solid-state laser, a fundamental wave, a second harmonic, or a third or higher harmonic is used. In the laser, for example, a monocrystal of YAG, YLF, YVO₄, forsterite, YAlO₃, or GdVO₄ which is doped with ions of Nd³⁺ or the like, a polycrystal of YAG, YLF, Y₂O₃, YVO₄, YAlO₃, or GdVO₄ which is doped with ions of Nd³⁺ or the like, can be used. In these lasers, pulsed oscillation can be performed at a repetition rate of 1 MHz or more by performing a Q-switch operation or mode locking. In the lasers described above, laser light is emitted mainly at a wavelength of 263 nm, 266 nm, 347 nm, 351 nm, or 355 nm.

In the present invention, a solid-state laser of pulsed oscillation with a repetition rate of 1 MHz or more, preferably 5 MHz or more, more preferably 50 MHz or more, still more preferably 80 MHz or more is used as a laser source. Hereinafter, advantages thereof are described.

In using a solid-state laser of pulsed oscillation, there are a period in which laser light is oscillated and a period in which laser light is not oscillated in a cycle of oscillation. For example, a laser with a repetition rate of 80 MHz has a cycle of 12.5 ns. The length of period in which laser light is oscillated is generally referred to as “pulse width”, and the representative value is 5 to 20 ps (FWHM). That is to say, the pulse width of laser light is only 1/1000 period of one cycle. With a laser exposure apparatus of the present invention, as a result, a resist film which is heated due to laser light exposure can be cooled off every cycle. With a light exposure apparatus of the present invention, heat expansion of a resist can be suppressed even when the resist is exposed to laser light with high energy. As a result, dimensional accuracy of an exposed pattern can be improved. Similarly, with a light exposure apparatus of the present invention, heat expansion of a light-shielding film of a photomask and a hologram mask can be suppressed even when the light-shielding film and the hologram mask are exposed to laser light with high energy. As a result, deterioration of these masks can be suppressed. It is desirable that the pulse width of laser light be 1/100 or smaller one cycle, preferably 1/200 or smaller, and more preferably 1/500 or smaller one cycle; i.e., in terms of time, 1 ns or shorter, preferably 100 ps or shorter, and more preferably 50 ps or shorter.

As a laser source used in the light exposure process, an argon ion laser is used at present. However, an argon ion laser used in light exposure apparatus is unstable. Further, an argon ion laser used for a light exposure apparatus has a short life span as an optical projection system and maintenance is frequently required, which costs too much. Furthermore, an argon ion laser used for a light exposure apparatus requires much power and generates much heat, and thus costs for temperature adjustment with air-conditioning units or the like increases. Still furthermore, an argon ion laser as an optical projection system is large-sized and is not suitable for reduction in space or increase in size of the apparatus, which accompanies increase in size of a substrate. Alternatively, a high-pressure mercury lamp is sometimes used as a light source in a light exposure process. However, a high-pressure mercury lamp used for a light exposure apparatus is unstable and requires frequent replacement. Further, a high-pressure mercury lamp used for a light exposure apparatus includes mercury, which can have a bad influence on environment when it is disposed of.

A light exposure apparatus called a stepper or a scanner, which uses excimer laser as a laser source of a light exposure process in making a semiconductor device, has a repetition rate of 2 to 4 kHz at the maximum. Therefore, when a scanner light exposure apparatus including an excimer laser is used for a large-sized glass substrate which forms a flat panel display or the like, it is difficult to fulfill both throughput and uniformity because of the low repetition rate. For example, a repetition rate, a scanning speed, and a beam width in a direction of movement on an irradiation surface of a resist or the like are supposed to be 4 kHz, 30 cm/sec, and 0.5 mm, respectively. In this case, one spot is exposed to laser light 6.7 times in average, the movement rate is 75 μm every pulse, and the overlap percentage of the beam is 85%. The boundary of an overlapping region (referred to as “joint”, hereinafter) is given energy (also referred to as “light exposure amount”) which is different from that given to another region. The difference in light exposure amount varies greatly according to energy distribution of a beam. A joint of 75 μm means that a region with different light exposure amount appears every 75 μm, and thus a region with different dimension appears every 75 μm in a resist after development or the like. As a result, the uniformity decreases in a body to be exposed to light, unfortunately. Further, an excimer laser occasionally has a mis-shot, which has an abnormal value of energy in 1 pulse. If such a mis-shot arises, it is difficult to even out the light exposure amount in a moving direction of the beam with an average exposure frequency of 6.7 times.

In the case where an excimer laser with a repetition rate of, for example, 4 kHz is used, one spot is exposed to laser light 200 times in average, the movement rate is 2.5 μm every pulse, and the overlap percentage of the beam is 99.5% under the condition that the scanning speed is 1 cm/sec and the beam width in a direction of movement is 0.5 mm. Even if scanning with laser light is performed relatively slowly in such a way, when the excimer laser with a repetition rate of 4 kHz is used, joints with different dimensions appear every 2.5 μm if the minimum size of a semiconductor device, e.g. a TFT, is 0.5 μm. Thus, a resist pattern becomes uneven. Moreover, an excimer laser is not suitable for a laser source of a light exposure apparatus due to wide variation of outputs between pulses.

Although a scanning speed in this specification denotes a relative speed of laser light and a substrate, there is a range of the speed between increase and decrease of the speed. Therefore, a scanning speed in the present invention means a maximum value in a relative speed of laser light and a substrate, and is referred to as a scanning speed, hereinafter.

With a solid-state laser of pulsed oscillation of the present invention, with a repetition rate of 1 MHz or more, e.g. of 1 MHz, one spot is exposed to laser light about 20,000 times in average, the movement rate is 50 nm every pulse, and the overlap percentage of the beam is 99.995% under the condition that the scanning speed is 5 cm/sec or more, for example, 5 cm/sec and the beam width in a direction of movement is 1 mm. When a solid-state laser with a repetition rate of 1 MHz or more is used, joints with different dimensions appear every 50 nm; however, a semiconductor device can be made with reduced variation because the minimum size of a semiconductor device, e.g. a thin film transistor, is about 0.5 μm. When a solid-state laser with a repetition rate of, for example, 1 MHz, is used, one spot is exposed to laser light about 5,000 times in average, the movement rate is 0.1 μm every pulse, and the overlap percentage of the beam is 99.98% under the condition that the scanning speed is 5 cm/sec, for example, 10 cm/sec and the beam width in a direction of movement is 0.5 mm. When a solid-state laser with a repetition rate of 1 MHz is used, joints with different dimensions appear every 0.1 μm; however, a semiconductor device can be made with reduced variation because the minimum size of a semiconductor device, e.g. a thin film transistor, is about 0.5 μm.

In using a solid-state laser with a repetition rate of 1 MHz, when laser light is emitted about 20,000 times in average at a scanning speed of 5 cm/sec and with a beam width in a direction of movement of 1 mm, the power of the solid-state laser is 8 W, and the energy from the laser light to which an irradiation surface is exposed is about 160 mJ/cm² when the beam width in a direction which is perpendicular to a direction of movement is 100 mm. This is enough energy for a resist for a large glass substrate, e.g. RG-300 manufactured by AZ Electronic Materials If the energy is too high to a material of the irradiation surface, the surface can be irradiated with reduced power of the solid-state laser. In a light exposure apparatus, when a glass substrate, e.g. a glass of 600 mm×720 mm in plane is supposed to be used, it takes about 80 seconds to irradiate the glass substrate, which is good takt time. However, the actual takt time is more than the above since the above time does not include the time of substrate conveyance, alignment, and the like.

When the scanning speed is 10 cm/sec or more, for example, 10 cm/sec, the takt time can be reduced since the time for light exposure can be halved. If the power a solid-state laser is 8 W and the other conditions than a scanning speed are the same as the above conditions, the energy from the laser light to which a surface is exposed is about 80 mJ/cm², which is enough for exposure of a resist.

With a solid-state laser of pulsed oscillation of the present invention, variation in intensity between pulses can be reduced compared to using an excimer laser. Further, on a surface to be exposed by a light exposure apparatus, the intensity of laser light per spot can be evened out since light exposure per spot is repeated quite a number of times. Therefore, variation in energy given to the surface by the laser light can be reduced.

With a solid-state laser with a repetition rate of 5 MHz or more, e.g. of 5 MHz, one spot is exposed to laser light about 8,300 times in average, the movement rate is 0.06 μm every pulse, and the overlap percentage of the beam is 99.988% under the condition that the scanning speed is 30 cm/sec and the beam width in a direction of movement is 0.5 mm. When the solid-state laser with a repetition rate of 5 MHz is used, joints with different dimensions appear every 0.06 μm; however, a semiconductor device can be made with reduced variation because the minimum size of a semiconductor device, e.g. a thin film transistor, is about 0.5 μm.

With a solid-state laser with a repetition rate of 50 MHz or more, e.g. of 50 MHz, one spot is exposed to laser light about 500,000 times in average, the movement rate is 2 nm every pulse, and the overlap percentage of the beam is 99.9998% under the condition that the scanning speed is 10 cm/sec or more, e.g. 10 cm/sec, and the beam width in a direction of movement is 1 mm. When the solid laser with a repetition rate of 50 MHz is used, one spot is exposed to laser light about 250,000 times in average, the movement rate is 4 nm every pulse, and the overlap percentage of the beam is 99.9996% under the condition that the scanning speed is 20 cm/sec or more, e.g. 20 cm/sec, and the beam width in a direction of movement is 1 mm. When the solid-state laser with a repetition rate of 50 MHz is used, one spot is exposed to laser light about 170,000 times in average, the movement rate is 6 nm every pulse, and the overlap percentage of the beam is 99.9994% under the condition that the scanning speed is 30 cm/sec or more, e.g. 30 cm/sec, and the beam width in a direction of movement is 1 mm. When the solid-state laser with a repetition rate of 50 MHz is used, one spot is exposed to laser light about 80,000 times in average, the movement rate is 6 nm every pulse, and the overlap percentage of the beam is 99.9988% under the condition that the scanning speed is 30 cm/sec or more, e.g. 30 cm/sec, and the beam width in a direction of movement is 0.5 mm. When the solid-state laser with a repetition rate of 50 MHz is used, joints with different dimensions appear every 2 to 6 nm; however, a semiconductor device can be made with reduced variation because the minimum size of a semiconductor device, e.g. a thin film transistor, is about 0.5 μm.

With a solid-state laser with a repetition rate of 80 MHz or more, e.g. of 80 MHz, one spot is exposed to laser light about 130,000 times in average, the movement rate is 3.8 nm every pulse, and the overlap percentage of the beam is 99.99925% under the condition that the scanning speed is 30 cm/sec or more, e.g. 30 cm/sec, and the beam width in a direction of movement is 0.5 mm. When the solid-state laser with a repetition rate of 80 MHz is used, one spot is exposed to laser light about 400,000 times in average, the movement rate is 1.3 nm every pulse, and the overlap percentage of the beam is 99.99975% under the condition that the scanning speed is 10 cm/sec or more, e.g. 10 cm/sec, and the beam width in a direction of movement is 0.5 mm. When the solid-state laser with a repetition rate of 80 MHz is used, joints with different dimensions appear every 1.3 to 3.8 nm; however, a semiconductor device can be made with reduced variation because the minimum size of a semiconductor device, e.g. a thin film transistor, is about 0.5 μm.

In using a solid-state laser with a repetition rate of 80 MHz, when laser light is emitted about 130,000 times in average at a scanning speed of 30 cm/sec or more, e.g. 30 cm/sec, and with a beam width in a direction of movement of 0.5 mm, the power of the solid-state laser is 20 W, and the energy from the laser light to which a surface is exposed is about 65 mJ/cm² when the beam width in a direction which is perpendicular to a direction of movement is 100 mm. In using a solid-state laser with a repetition rate of 80 MHz, when laser light is emitted about 400,000 times in average at a scanning speed of 10 cm/sec or more, e.g. 10 cm/sec, and with a beam width in a direction of movement of 0.5 mm, the power of the solid-state laser is 8 W, and the energy from the laser light to which a surface is exposed is about 80 mJ/cm² when the beam width in a direction which is perpendicular to a direction of movement is 100 mm. This is enough energy for a resist for a large glass substrate, e.g. RG-300 manufactured by AZ Electronic Materials.

The coherence length of an excimer laser is smaller than that of other lasers. Therefore, an excimer laser is not suitable for making a hologram or a light exposure apparatus to which a reproduction phenomenon is applied. On the other hand, in a light exposure apparatus to which holography is applied, laser light with a large coherence length is split into two beams, i.e., a reference beam and an object beam by a beam splitter and these beams are made to interfere with each other, so that the resulting fringe pattern is recorded in a photosensitive material or the like. If the laser light has a large coherence length, the beams can interfere with each other even if the optical path difference between the reference beam and the object beam is long. If the laser light has a small coherence length, however, the optical path difference is required to be shortened, which is not realistic. In particular, an excimer laser with a small coherence length is not suitable for making a hologram mask intended for a total-reflection holographic light exposure apparatus. Therefore, in a light exposure apparatus to which holography is applied, there is an advantage that a light exposure apparatus with higher precision can be made by using a solid-state laser with a large coherence length as in the present invention.

According to the present invention, as explained above, it is preferable to use a solid-state laser with a repetition rate of 1 MHz or more, more preferably 5 MHz or more, still more preferably 50 MHz or more, even still more preferably 80 MHz or more.

Furthermore, in the present invention, the maximum value of the scanning speed, which is a relative speed of laser light and a substrate, can be set at 5 cm/sec or more, preferably at 10 cm/sec or more, more preferably at 20 cm/sec or more, still more preferably at 30 cm/sec or more in addition to employing the structure in which a solid-state laser with the above repetition rate is employed. In this manner, variation in line width in making semiconductor devices formed using a light exposure apparatus can be suppressed, and further, a light exposure apparatus with considerably reduced takt time can be made.

In the photomask 104 in FIG. 1, a desired line pattern is formed by processing the light-shielding film minutely, and the laser light transmits or does not transmit depending on the presence of the light-shielding film.

If a hologram or a computer-generated hologram is used as a mask, interference fringes are formed on the mask, in the mask, or both on and in the mask according to the difference of transmission rates or refractive indexes of laser light.

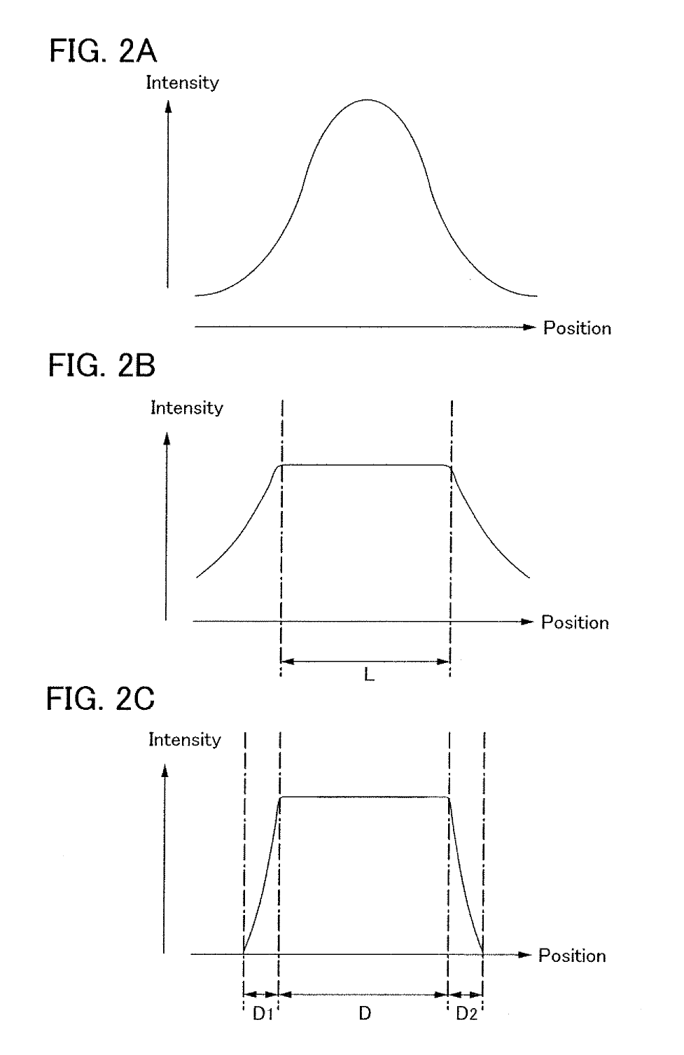

The laser light emitted from the laser source 101 in FIG. 1 is processed into a linear shape and has, in a long-axis direction, an intensity distribution as shown in FIG. 2A. The laser light passes through the beam optical system 102 and the intensity distribution of the laser light is shaped into a quadrangle or trapezoid as shown in FIG. 2B, so that the intensity distribution of the laser light can be close to uniform. When the intensity distribution of the laser light is shaped as shown in FIG. 2B, the laser light may be processed with a slit or the like so that an irradiation surface will be exposed to a flat part of the laser light having the intensity distribution of a quadrangle or trapezoid shape (an area which is indicated with L in FIG. 2B).

The laser light emitted from the laser source 101 in FIG. 1 is processed into a linear shape and has, in a short-axis direction, an intensity distribution as shown in FIG. 2C. The laser light passes through the beam optical system 102 and the intensity distribution of the laser light is shaped into a quadrangle or trapezoid as shown in FIG. 2C, so that the intensity distribution of the laser light can be close to uniform. Although an ideal shape of the intensity distribution of the formed laser light is a quadrangle, as shown in FIG. 2C, the shape is a trapezoid, to be exact. Therefore, in the intensity distribution of the laser light in a short-axis direction, a flat part of the top of the trapezoid-shaped intensity distribution (an area which is indicated with D in FIG. 2C) corresponds to a part of laser beams to be overlapped in a light exposure apparatus. As for the intensity distribution of the laser light in a short-axis direction, note that edge portions of the trapezoid-shaped intensity distribution can cause variation in the degree of light exposure, and are each referred to as an edge portion D1 and an edge portion D2 so that advantages of the present invention is explained afterwards.

In FIG. 1, the laser light emitted from the laser source 101 is shaped and evened up as shown in FIGS. 2A, 2B, and 2C by the beam optical system 102, and is emitted to the photomask 104 via the mirror 103 interposed therebetween. The photomask 104 is exposed to the laser light so that the entire photomask is scanned. The laser light emitted to the photomask 104 is or is not transmitted according to a light-transmitting portion and a light-shielding portion which are formed on the photomask 104. The laser light transmitted through the photomask 104 is optionally adjusted at the same magnification, is reduced, or is magnified by the projection optical system 105. And then the substrate 107 over the substrate stage 106 is exposed to the laser light.

Before the laser light exposure, a photosensitive photoresist (also simply referred to as a resist) is formed over the entire irradiation surface on the substrate 107. As the photoresist formed over the substrate 107, a positive photoresist, a negative photoresist, or the like can be used as appropriate. As for a method for forming the photosensitive photoresist, known methods such as an application method can be used. In this description, a case is explained where a negative photoresist, in which an irradiated portion of a resist film remains, is used since an exposure rate of laser light, i.e. light exposure intensity, is explained. However, whether a positive photoresist or a negative photoresist is used, the present invention can be applied.

As the substrate 107, a substrate on which microfabrication can be provided, such as a single crystal silicon wafer, a glass substrate, a quartz substrate, an SOI substrate, a ceramics substrate, or a plastic substrate, is appropriate. Of course, the substrate 107 is not limited to the above, and the substrate 107 may be made of any material as long as it requires processing by light exposure.

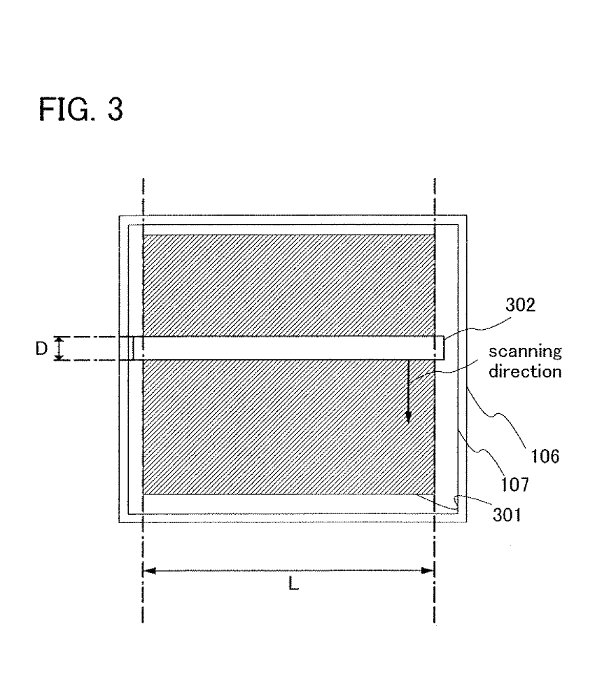

As shown in FIG. 3, a resist 301 is formed over the entire surface of the substrate 107. The resist 301 is not necessarily required to be formed in advance over an area where an element such as wires is not formed. And the resist 301 which is provided for the substrate 107 over the substrate stage 106 is exposed to the laser light through the photomask 104 in FIG. 1. The laser light which is transmitted through the photomask 104 is formed into a linear shape by the beam optical system 102 in FIG. 1, and emitted on the resist 301 over the substrate 107 as laser light 302 having a shape shown in FIG. 3.

The intensity distribution of the laser light is illustrated in FIG. 2B for explanation. In the shape of the laser shown in FIG. 3, the length in the direction perpendicular to the scanning direction of the laser light, i.e. the length of a long side of an irradiation surface of the laser light, is L; and the length in the direction parallel to the scanning direction of the laser light, i.e. the length of a short side of an irradiation surface of the laser light, is D. The L which is illustrated in FIG. 3 and corresponds to the length of the long side of the irradiation surface of the laser light has a length which corresponds to a flat part of the trapezoid-shaped intensity distribution shown in FIG. 2B.

When there is an emphasis on a high throughput and reduction of takt time, the resist film is expected to be exposed to the laser light so that the irradiation surface of the laser light will not overlap each other. As for pulsed laser light, however, there arises variation in light exposure of the resist film due to the variation in intensity distribution of the laser light energy. In particular, when D1 and D2 of the intensity distribution of the laser light in the short axis of the scanning direction, which are illustrated in FIG. 2C, are long, that is, when Gaussian distribution is noticeable, variation in light exposure arises. Thus, one feature of the present invention is that in order to reduce the variation in light exposure when the pulsed laser light is used as a laser source, the laser light is emitted to the resist film, i.e. the irradiation surface, as the irradiation surface shifts so as to overlap each other in the scanning direction. Here, the irradiation surface of the laser light shifts in the scanning direction by less than D, the short length of the irradiation surface of the laser light shown in FIG. 3, in a period of 1/f (the f is a repetition rate of the pulsed laser light).

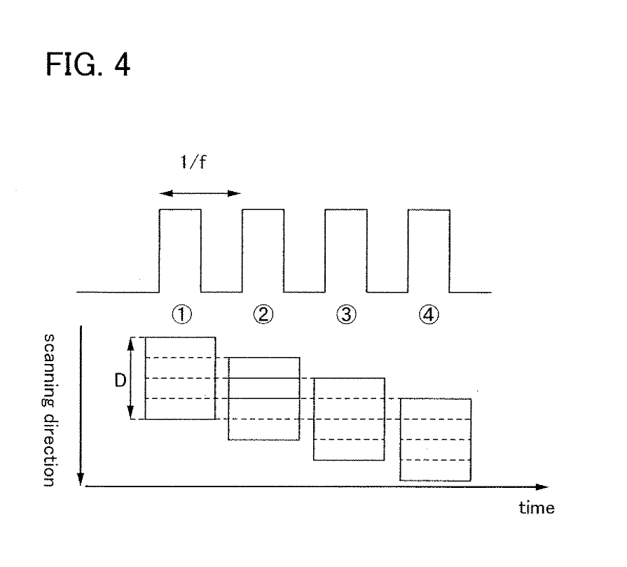

More concrete explanation is given with reference to FIG. 4. FIG. 4 illustrates a pulse wave pattern of laser light and temporal change of scanning of the irradiation surface with the laser light. In the wave pattern of the laser light shown in FIG. 4, when f is a repetition rate of pulsed laser light, one wavelength is 1/f, that is, the length of period illustrated in the drawing. In FIG. 4, the irradiation surface is exposed to the laser light every pulse. In this time, when the length of a short side of the irradiation surface of the laser light is D, the irradiation surface of the laser light shifts by D/n (n>1) every pulse. Here, the overlap percentage (also referred to as a superposition percentage) of the irradiation surfaces of the laser light in the n-th (n is a natural number) pulse and the (n+1)-th pulse is [{1−(1/n)}×100] (%). In an example shown in FIG. 4, the irradiation surface of the laser light shifts by D/4 every pulse, and the overlap percentage of the laser light in the n-th pulse and the (n+1)-th pulse is 75%. That is to say, the laser light scans by the distance D with 4 pulses in 4/f seconds, so that the irradiation surface is exposed to the laser light 4 times.

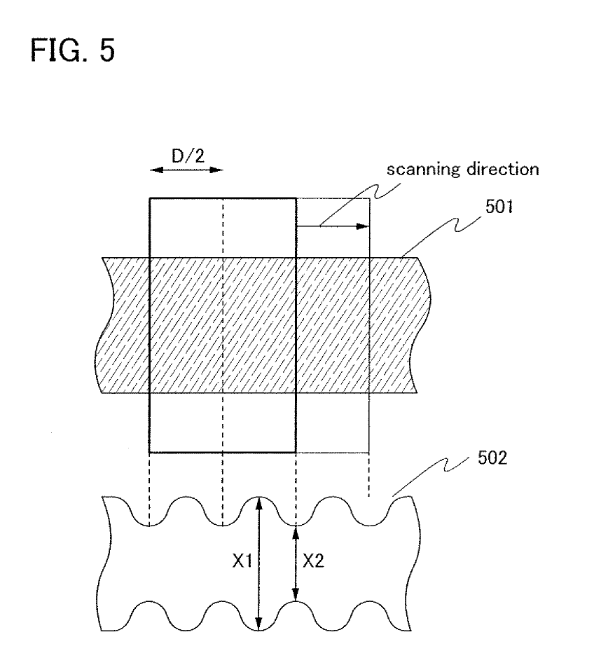

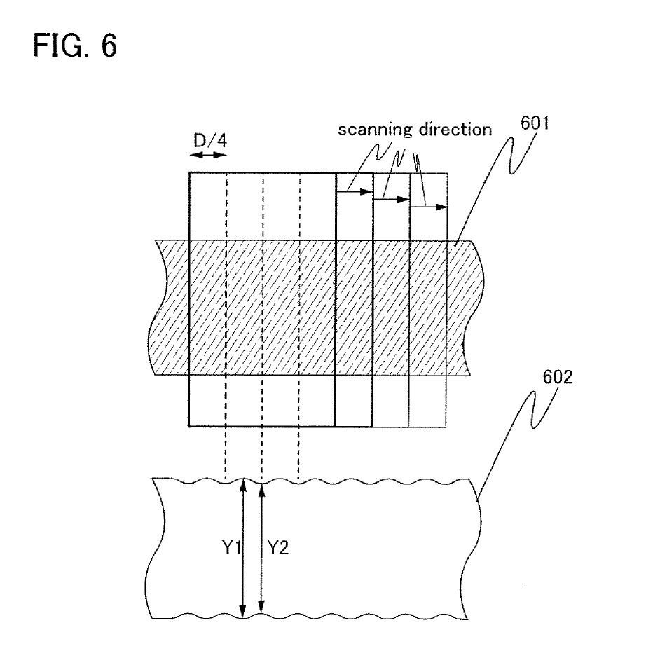

Next, the correlation between the overlap percentage and repetition rate of laser light emitted from a pulsed laser used as a laser source in the present invention is explained in detail with reference to FIGS. 5 to 7B. FIG. 5 illustrates an example where the irradiation surface of the laser light shifts by D/2 every pulse, and the overlap percentage of the laser light in the n-th pulse and the (n+1)-th pulse is 50%. FIG. 6 illustrates an example where the irradiation surface of the laser light shifts by D/4 every pulse, and the overlap percentage of the laser light in the n-th pulse and the (n+1)-th pulse is 75%. FIGS. 7A and 7B illustrate pulse wave patterns of laser light when the repetition rates of laser light emitted from the pulsed laser source are f₁ and f₂, and temporal change of scanning of the irradiation surface with the laser light. Here, the correlation of the repetition rates f₁ and f₂ is f₁<f₂.

In FIG. 5, the irradiation surface shifts by D/2 every pulse of the laser light, and the overlap percentage of the n-th pulse and the (n+1)-th pulse is 50%. Therefore, degree of exposure of a resist depends on the variation of intensity distribution of the laser light shown in FIGS. 2A to 2C. Consequently, in FIG. 5, when a region exposed to light is a region 501 and a negative photoresist, in which irradiated parts remain, is used, the resist remains in the shape of a resist 502 after development. As shown in the resist 502 in FIG. 5, the remaining linear-shaped resist has a line width X1 and a line width X2. The line widths XL and X2 in the remaining linear-shaped resist depend on variation in laser light exposure.

In FIG. 6, the irradiation surface shifts by D/4 every pulse of the laser light, and the overlap percentage of the n-th pulse and the (n+1)-th pulse is 75%. Therefore, similarly to the case of FIG. 5, degree of exposure of a resist depends on the variation of intensity distribution of the laser light shown in FIGS. 2A to 2C. Consequently in FIG. 6, when a region exposed to light is a region 601 and a negative photoresist, in which irradiated parts remain, is used, the resist remains in the shape of a resist 602 after development. As shown in the resist 602 in FIG. 6, the remaining linear-shaped resist has a line width Y1 and a line width Y2. Similarly to the case of FIG. 5, the line widths Y1 and Y2 in the remaining linear-shaped resist depend on variation in laser light exposure.

FIG. 7A illustrates a pulse wave pattern of laser light when the repetition rate of laser light emitted from the pulsed laser source is f₁, and temporal change of scanning of the irradiation surface with the laser light. FIG. 7B illustrates a pulse wave pattern of laser light when the repetition rate of laser light emitted from the pulsed laser source is f₂₇ and temporal change of scanning of the irradiation surface with the laser light. Here, in FIG. 7A, the laser light scans by the distance D with 4 pulses in 4/f₂ seconds. In FIG. 7B, the laser light scans by the distance D with 4 pulses in 4/f₂ seconds. As descried above, the correlation of the repetition rates f₁ and f₂ is f₁<f₂; as a result, the higher the repetition rate is, the shorter it takes to scan the same distance under the same overlap percentage.

As illustrated in FIGS. 5 to 7B, a light exposure apparatus of the present invention can be provided, in which the repetition rate of laser light emitted from the laser source is high and the overlap percentage of the laser light on the irradiation surface is high, so that light exposure is performed with high throughput, i.e. with a small variation in short takt time.

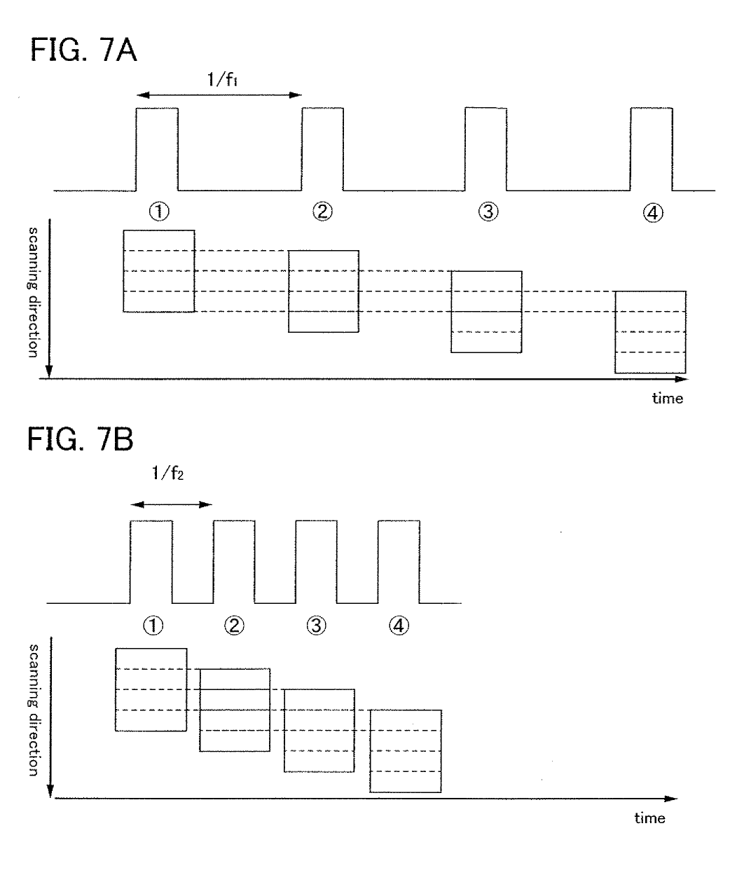

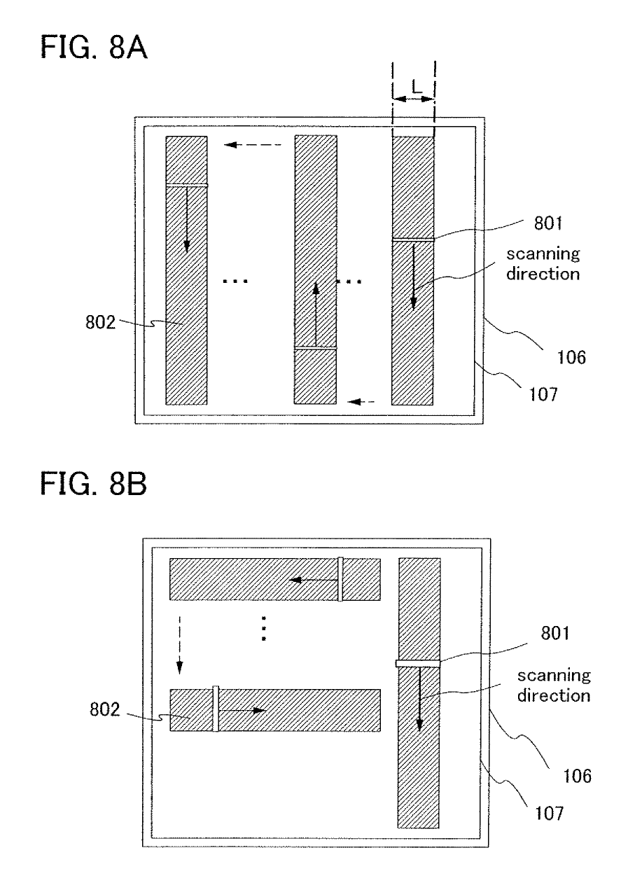

With regard to the light exposure apparatus of the present invention, when the L, which corresponds to the length of a long side of the irradiation surface of the laser light, substantially corresponds to the flat part of the trapezoid-shaped laser light shown in FIG. 2B, it is possible that the surface cannot completely be exposed to the laser light in one crossing. In this case, it is preferable that the irradiation surface be scanned with the laser light back and forth according to a mask pattern of the irradiation surface, as shown in FIGS. 8A and 8B. In the case of FIG. 8A, it is preferable that the substrate 107 over the substrate stage 106 be scanned with laser light 801 back and forth a plurality of times. As shown in FIG. 8B, alternatively, the irradiation surface may be scanned back and forth, with the scanning direction changed.

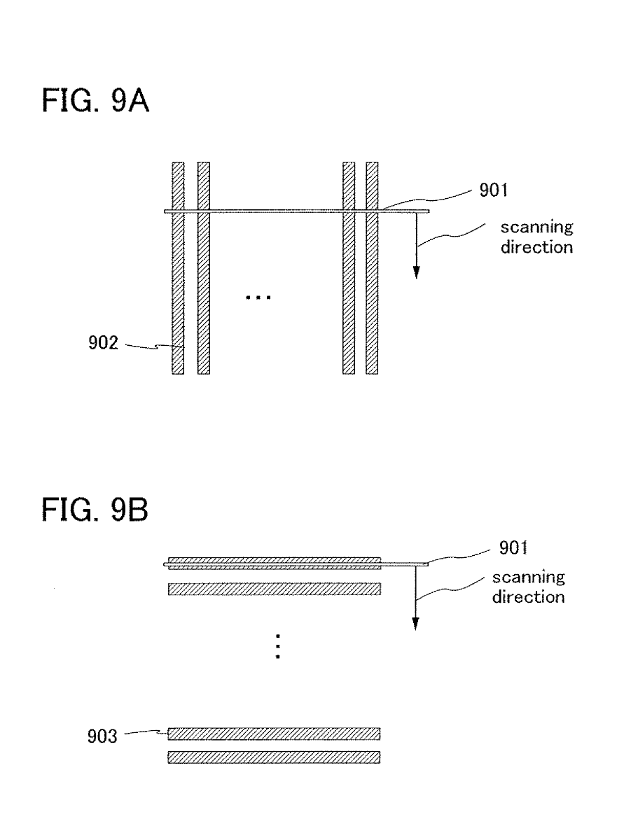

When the irradiation surface is exposed to the light as shown in FIGS. 8A and 8B, the scanning direction may be changed according to a mask pattern of a photomask. As shown in FIG. 9A, for example, the resist film, i.e. the irradiation surface may be scanned with linear-shaped laser light 901 in a direction parallel to a long side of a mask pattern 902. Alternatively, as shown in FIG. 9B, the resist film, i.e. the irradiation surface may be scanned with linear-shaped laser light 901 in a direction perpendicular to a long side of a mask pattern 903.

With the light exposure apparatus of the present invention, light exposure may be performed a plurality of times using one or more masks with the same pattern by moving the masks relatively to the substrate. Furthermore, light exposure may be performed with any combination of a photomask, a hologram, and a computer-generated hologram before development.

With the light exposure apparatus, as described above, the variation in laser light exposure of the irradiation surface can be suppressed. Consequently, variation in line width such as that of wires can be suppressed in the semiconductor devices, so that the defect rate of semiconductor devices can be suppressed. Therefore, a yield in semiconductor devices can be improved and semiconductor devices with reduced variation can be made.

In addition, with the light exposure apparatus of the present invention, improvement in throughput in the light exposure process of the semiconductor device can be expected since the speed of scanning a substrate can be increased. Therefore, takt time can be reduced considerably in a method for making the semiconductor devices using one substrate.

### Embodiment Mode 1

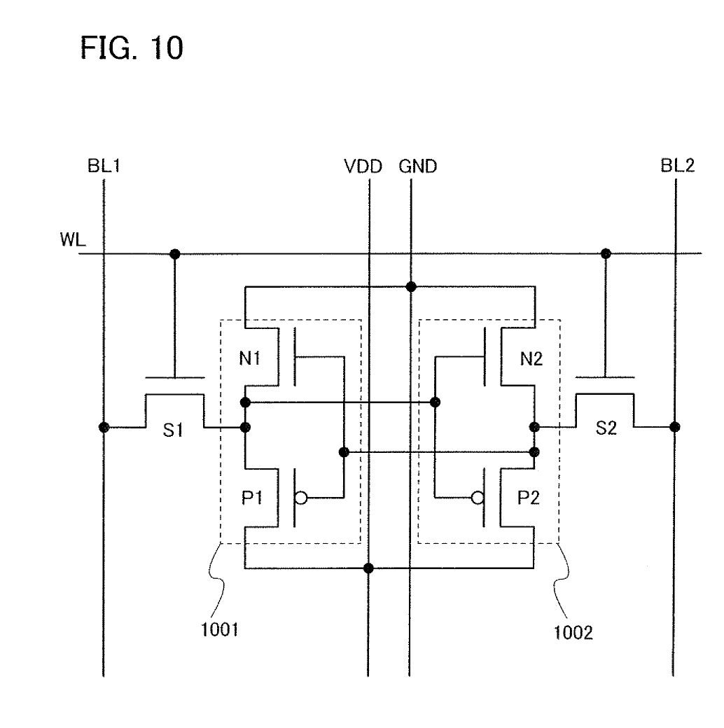

A method for making a semiconductor device formed using the light exposure apparatus of the present invention is explained with reference to the drawings. In the following, as shown in FIG. 10, a cell of a static random access memory (SRAM) which includes six transistors is explained as an example.

The SRAM includes inverters 1001 and 1002, and the inputs of the inverters 1001 and 1002 are connected to bit lines BL1 and BL2 through switches S1 and S2, respectively. The switches S1 and S2 are controlled by a row selection signal which is transmitted through a word line WL. The inverters 1001 and 1002 are supplied with power by a high voltage VDD and a low voltage GND, which is generally grounded. In order to write data into the memory cell, the voltage VDD is applied to one of the bit lines BL1 and BL2, while the voltage GND is applied to the other of the bit lines.

The inverter 1001 includes an n-channel transistor N1 and a p-channel transistor P1 connected in series. The source of the p-channel transistor P1 is connected to the voltage VDD, and the source of the n-channel transistor N1 is connected to the voltage GND. The drains of the p-channel transistor P1 and the n-channel transistor N1 are connected to each other, and the gates of the p-channel transistor P1 and the n-channel transistor N1 are also connected to each other. Similarly, the inverter 1002 includes a p-channel transistor P2 and an n-channel transistor N2, which are connected in series similarly to the p-channel transistor P1 and the n-channel transistor N1. The gates of the p-channel transistor P2 and the n-channel transistor N2 are connected to each other, and drains of the p-channel transistor P2 and the n-channel transistor N2 are also connected to each other as a common drain.

The SRAM shown in FIG. 10 operates in the following way: the switches S1 and S2 are turned on to set the input/output states of the inverters 1001 and 1002; then the switches S1 and S2 are turned off to retain the signal status of the inverters 1001 and 1002; in order to read out data from the memory cell, the bit lines BL1 and BL2 are precharged to have voltages ranging from VDD to GND; the switches S1 and S2 are turned on, and the voltages of the bit lines change according to the status of the signal which is stored by the inverters 1001 and 1002; and data stored in the memory cell is read out by a sense amplifier which is connected to each bit line.

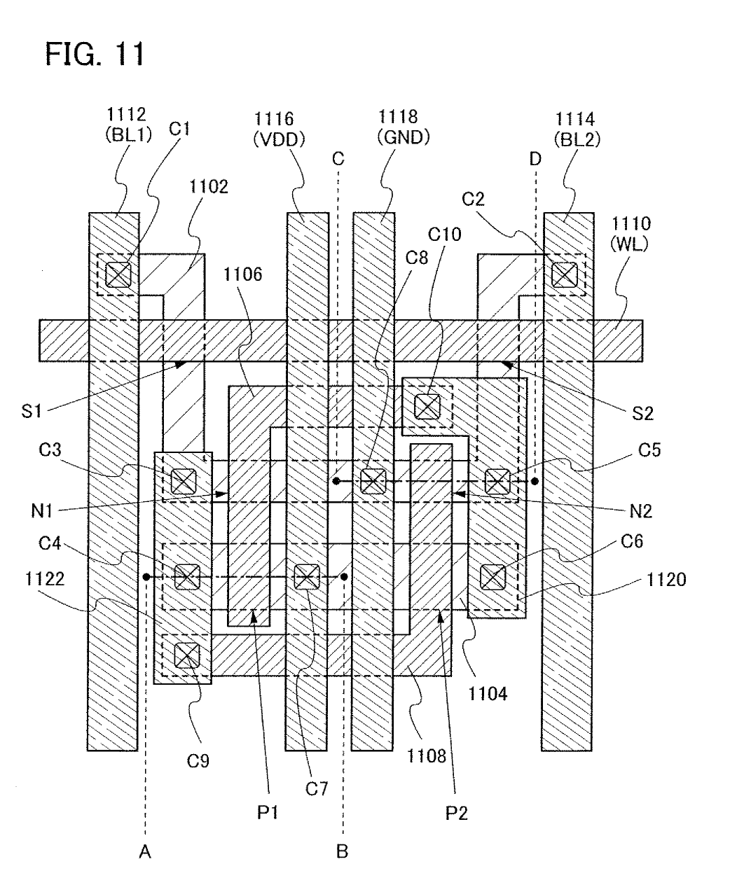

FIG. 11 illustrates an example of a circuit layout of the SRAM shown in FIG. 10. FIG. 11 shows the SRAM which includes a semiconductor layer and two wiring layers including a gate wiring layer. Given that a semiconductor layer 1102 for forming n-channel transistors and a semiconductor layer 1104 for forming p-channel transistors are located in the lower layer, first wiring layers 1106, 1108, and 1110 are located above the lower layer with a second insulating layer 1103 interposed therebetween. The first wiring layer 1106 is a layer for forming gate electrodes, and forms the n-channel transistor N1 and the p-channel transistor P1, intersecting the semiconductor layers 1102 and 1104, respectively. The first wiring layer 1108 is a layer for forming gate electrodes, and forms the n-channel transistor N2 and the p-channel transistor P2, intersecting the semiconductor layers 1102 and 1104, respectively. The first wiring layer 1110 is a word line (WL), and forms the switches S1 and S2, intersecting the semiconductor layer 1102. In this manner, the first wiring layers 1106, 1108, and 1110 intersect the semiconductor films 1102 and 1104 to form gate electrodes.

Second wiring layers 1112, 1114, 1116, and 1118 are formed above the first wiring layers 1106, 1108, and 1110 with a third insulating layer 1134 and a fourth insulating layer 1136 interposed therebetween. The second wiring layer 1112 forms a bit line (BL1). The second wiring layer 1114 forms a bit line (BL2). The second wiring layer 1116 forms a power supply line (VDD). The second wiring layer 1118 forms a ground potential line (GND).

A contact hole C1 is an opening formed in the third insulating layer 1134 and the fourth insulating layer 1136, and the second wiring layer 1112 and the semiconductor layer 1102 are connected through the contact hole C1. A contact hole C2 is an opening formed in the third insulating layer 1134 and the fourth insulating layer 1136, and the second wiring layer 1114 and the semiconductor layer 1102 are connected through the contact hole C2. A contact hole C3 is an opening formed in the third insulating layer 1134 and the fourth insulating layer 1136, and the second wiring layer 1122 and the semiconductor layer 1102 are connected through the contact hole C3. A contact hole C4 is an opening formed in the third insulating layer 1134 and the fourth insulating layer 1136, and the second wiring layer 1122 and the semiconductor layer 1104 are connected through the contact hole C4. A contact hole C5 is an opening formed in the third insulating layer 1134 and the fourth insulating layer 1136, and the second wiring layer 1120 and the semiconductor layer 1102 are connected through the contact hole C5. A contact hole C6 is an opening formed in the third insulating layer 1134 and the fourth insulating layer 1136, and the second wiring layer 1120 and the semiconductor layer 1104 are connected through the contact hole C6. A contact hole C7 is an opening formed in the third insulating layer 1134 and the fourth insulating layer 1136, and the second wiring layer 1116 and the semiconductor layer 1104 are connected through the contact hole C7. A contact hole C8 is an opening formed in the third insulating layer 1134 and the fourth insulating layer 1136, and the second wiring layer 1118 and the semiconductor layer 1102 are connected through the contact hole C8. A contact hole C9 is an opening formed in the third insulating layer 1134 and the fourth insulating layer 1136, and the second wiring layer 1122 and the first wiring layer 1108 are connected through the contact hole C9. A contact hole C10 is an opening formed in the third insulating layer 1134 and the fourth insulating layer 1136, and the second wiring layer 1120 and the first wiring layer 1106 are connected through the contact hole C10. In this manner, the SRAM shown in FIG. 10 includes the contact holes C1 to C10, which connect the semiconductor films, the first wiring layers, and the second wiring layers.

Next, a process of making such an SRAM will be explained with reference to sectional views taken along a line A-B (the p-channel transistor P1) and a line C-D (n-channel transistor N2) in FIG. 11.

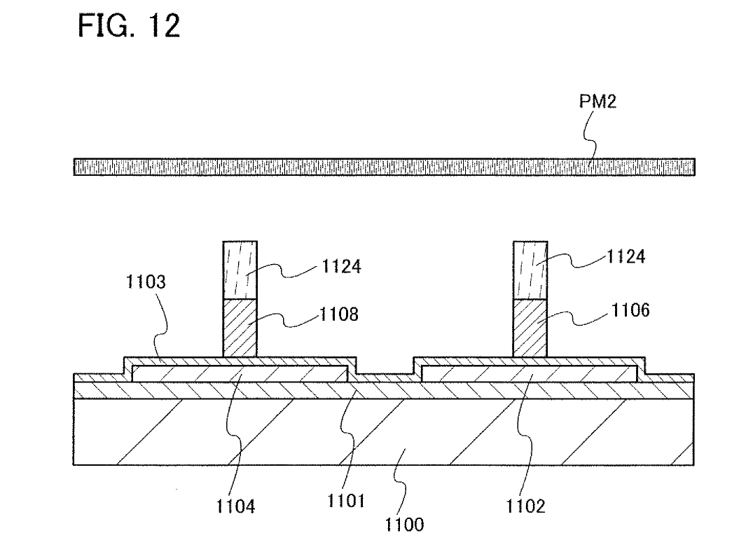

In FIG. 12, a material of the substrate 1100 is selected from among a glass substrate, a quartz substrate, a metal substrate (e.g., a ceramic substrate or a stainless steel substrate), and a semiconductor substrate such as a silicon substrate. Alternatively, the substrate 1100 can be a plastic substrate made of polyethylene terephthalate (PET), polyethylene naphthalate (PEN), polyethersulfone (PES), acrylic, or the like.

A first insulating layer 1101 is formed over the substrate 1100 as a blocking layer to impurities. The first insulating layer 1101 serves as a base film of the semiconductor layers 1102 and 1104. If quartz is employed for the substrate 1100, the first insulating Layer 1101 can be omitted.

The first insulating layer 1101 is formed by a CVD method, a sputtering method, or the like, using an insulating material such as silicon oxide, silicon nitride, silicon oxynitride (SiOₓN_{y}), (x>y>0), or silicon nitride oxide (SiNₓO_{y}) (x>y>0). When the first insulating layer 1101 has a double-layer structure, for example, it is preferable to form a silicon nitride oxide film as a first insulating film and a silicon oxynitride film as a second insulating film. Alternatively, a silicon nitride film may be formed as the first insulating film and a silicon oxide film may be formed as the second insulating film. In this manner, forming the first insulating layer 1101, which functions as a blocking layer, can prevent an adverse effect of alkaline metals such as Na or alkaline earth metals contained in the substrate 1100, which would otherwise be diffused into elements formed over the substrate.

It is preferable to form crystalline semiconductor layers as the semiconductor layers 1102 and 1104. The crystalline semiconductor layer may be any of the following: a layer obtained by crystallizing an amorphous semiconductor layer formed over the first insulating layer 1101 by heat treatment or laser irradiation; a layer obtained by processing a crystalline semiconductor layer formed over the first insulating layer 1101 into an amorphous state and then recrystallizing it; and the like.

In the case of performing crystallization or recrystallization by laser irradiation, an LD-pumped continuous wave (CW) laser (e.g., YVO₄: a second harmonic (a wavelength of 532 nm)) can be used as a laser source. Although the frequency is not limited to the second harmonic, the second harmonic is superior to higher harmonics in energy efficiency. When a semiconductor film is irradiated with CW laser, energy is continuously given to the semiconductor film. Therefore, once the semiconductor film is placed in a molten state, the molten state can be retained. Further, by scanning the semiconductor film with the CW laser, a solid-liquid interface of the semiconductor film can be moved, and crystal grains which extend in a movement direction can be formed. The reason for using a solid-state laser is that the output is more stable compared with that of a gas laser or the like, and thus more stable treatment can be expected. The laser source is not limited to a CW laser, and a pulsed laser with a repetition rate of 10 MHz or higher can also be used. When a pulsed laser with a high repetition rate is used, the semiconductor film can be retained in the molten state if the pulse interval of the laser is shorter than the period from when the semiconductor film is melted and until when the semiconductor film gets solidified. Thus, the semiconductor film with crystal grains extending in one direction can be formed by moving the solid-Liquid interface. It is also possible to employ other types of CW lasers or pulsed lasers with a repetition rate of 10 MHz or higher. For example, gas lasers such as an Ar laser, a Kr laser, and a CO₂ laser can be used. Further, solid-state lasers such as a YAG laser, a YLF laser, a YAlO₃ laser, a GdVO₄ laser, a KGW laser, a KYW laser, an alexandrite laser, a Ti:sapphire laser, a Y₂O₃ laser, and a YVO₄ laser can be used. Furthermore, ceramic lasers such as a YAG laser, a Y₂O₃ laser, a GdVO₄ laser, and a YVO₄ laser can be used. Still furthermore, a metal vapor laser such as a helium-cadmium laser can be used. It is preferable that laser light be emitted from a laser oscillator with TEM₀₀ (single transverse mode), which can even up the energy of a linear beam spot obtained on the irradiation surface. Still furthermore, a pulsed excimer laser can also be used.

The second insulating layer 1103, which serves as a gate insulating layer, is formed using silicon oxide, silicon nitride, silicon oxynitride (SiOₓN_{y}) (x>y>0), silicon nitride oxide (SiNₓO_{y}) (x>y>0), or the like. Such an insulating layer is formed by a vapor deposition method or a sputtering method. Alternatively, the second insulating layer 1103, which serves as the gate insulating layer, can be formed by treating the surfaces of the semiconductor layers 1102 and 1104 with high-density plasma under an oxygen atmosphere (e.g., an atmosphere containing oxygen (O₂) and a rare gas (at least one of He, Ne, Ar, Kr, and Xe), or an atmosphere containing oxygen, hydrogen (H₂), and a rare gas) or under a nitrogen atmosphere (e.g., an atmosphere containing nitrogen (N₂) and a rare gas (at least one of He, Ne, Ar, Kr, and Xe), an atmosphere containing nitrogen, hydrogen, and a rare gas, or an atmosphere containing ammonia (NH₃) and a rare gas), thereby oxidizing or nitriding the surfaces of the semiconductor layers 1102 and 1104. By forming the second insulating layer 1103 through oxidizing or nitriding the surfaces of the semiconductor layers 1102 and 1104 with high-density plasma treatment, defect level density, which would be a cause of a trap of electrons or holes, can be reduced.

The first wiring layers 1106 and 1108, which serve as gate electrodes, are formed using a high-melting-point metal such as tungsten, molybdenum, titanium, tantalum, chromium, and niobium. Alternatively, an alloy of the above metals, conductive metal nitride, or conductive metal oxide can be used, e.g. an alloy of molybdenum and tungsten, titanium nitride, or tungsten nitride. Further alternatively, a stacked layer of tantalum nitride and tungsten can be used. Further alternatively, polysilicon which is doped with an impurity element such as phosphorus can be used.

In order to form the first wiring layers 1106 and 1108, which serve as gate electrodes, the aforementioned conductive layer is deposited almost over the entire surface of the second insulating layer 1103, and then a mask layer 1124 is formed using a photomask. The first wiring layers 1106 and 1108 are formed by etching with the use of the mask layer 1124. The mask layer 1124 is formed by an exposure process: at this time, light exposure is performed with the use of the photomask and the light exposure apparatus explained with reference to FIG. 1, so that the first wiring layers 1106 and 1108, which serve as gate electrodes with reduced variation in light exposure, can be formed at high throughput.

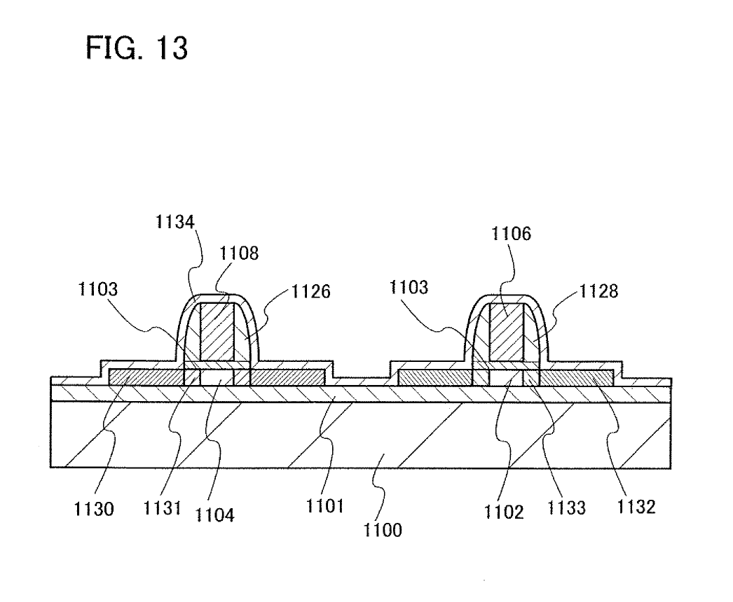

In FIG. 13, the first wiring layers 1106 and 1108 are provided with side spacers 1128 and 1126, respectively. In addition, the third insulating layer 1134 is formed for passivation. The third insulating layer 1134 is formed using silicon nitride, silicon oxynitride (SiOₓN_{y}) (x>y>0), silicon nitride oxide (SiNₓO_{y}) (x>y>0), or the like. In the semiconductor layer 1102, an n-type impurity region 1132, which serves as a source or a drain, is formed. In addition, a low-concentration drain region 1133 (a so-called LDD region) may be formed with the use of the side spacer 1128. In the semiconductor layer 1104, a p-type impurity region 1130, which serves as a source or a drain, is formed. In addition, a low-concentration drain region 1131 (a so-called LDD region) may be formed with the use of the side spacer 1126.

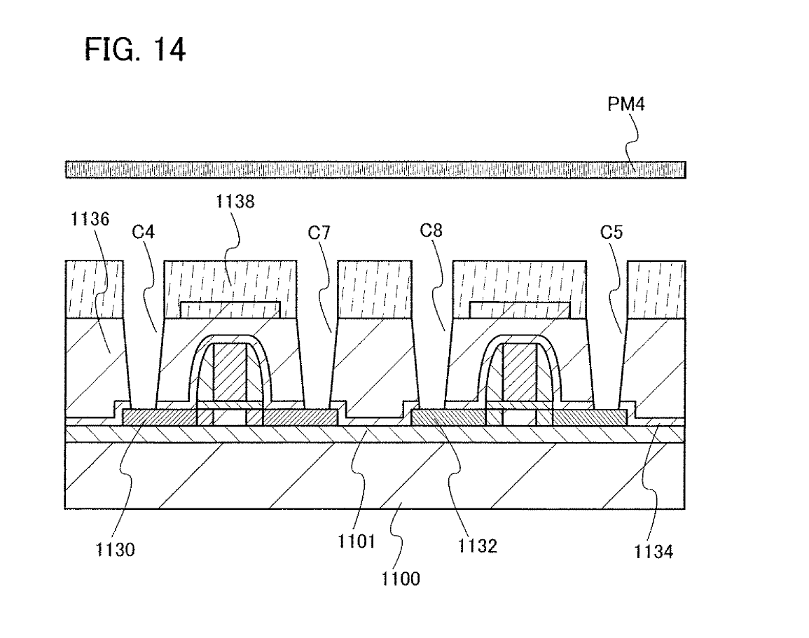

FIG. 14 illustrates a process in which the fourth insulating layer 1136 and contact holes C4, C5, C7, and C8 are formed. Silicon oxide, silicon oxynitride (SiOₓN_{y}) (x>y>0), silicon nitride oxide (SiNₓO_{y}) (x>y>0), or the like which is formed by a vapor deposition method, e.g. a plasma CVD method and a thermal CVD method, a sputtering method, or the like, is applied for the fourth insulating layer 1136. Alternatively, the fourth insulating layer 1136 can be formed to have a single-layer structure or a stacked-layer structure of an organic material such as polyimide, polyamide, polyvinyl phenol, benzocyclobutene, acrylic, or epoxy; a siloxane material such as siloxane resin; oxazole resin; and/or the like. The siloxane material is a material having Si—O—Si bonds. Siloxane has a skeletal structure constituted by the bond of silicon (Si) and oxygen (O). As a substituent of siloxane, an organic group containing at least hydrogen (e.g., an alkyl group or aromatic hydrocarbon) is used. Alternatively, a fluoro group may be used as the substituent. Further alternatively, both a fluoro group and an organic group containing at least hydrogen may be used as the substituent. Oxazole resin includes photosensitive polybenzoxazole, for example. Photosensitive polybenzoxazole is a material having a low dielectric constant (a dielectric constant of 2.9 at 1 MHz at room temperature), high heat resistance (a thermal decomposition temperature of 550° C. at a temperature rise of 5° C./min by TG/DTA (Thermogravimetry-Differential Thermal Analysis)), and low water absorption (0.3% for 24 hours at room temperature). Oxazole resin has a lower dielectric constant (about 2.9) as compared with that of polyimide (about 3.2 to 3.4) or the like. Therefore, generation of parasitic capacitance can be suppressed and high-speed operation can be performed.

The contact holes C4, C5, C7, and C8, which penetrate the third insulating layer 1134 and the fourth insulating layer 1136, and through which the n-type impurity region 1132 and the p-type impurity region 1130 are exposed, are formed using a mask layer 1138. The mask layer 1138 is formed by a light exposure process: at this time, light exposure is performed with the use of a photomask and the light exposure apparatus explained with reference to FIG. 1, so that the mask layer 1138 having contact holes and with reduced variation in light exposure, can be formed. After that, the third insulating layer 1134 and the fourth insulating layer 1136 are etched using the mask layer 1138, so that the contact holes C4, C5, C7, and C8 can be formed.

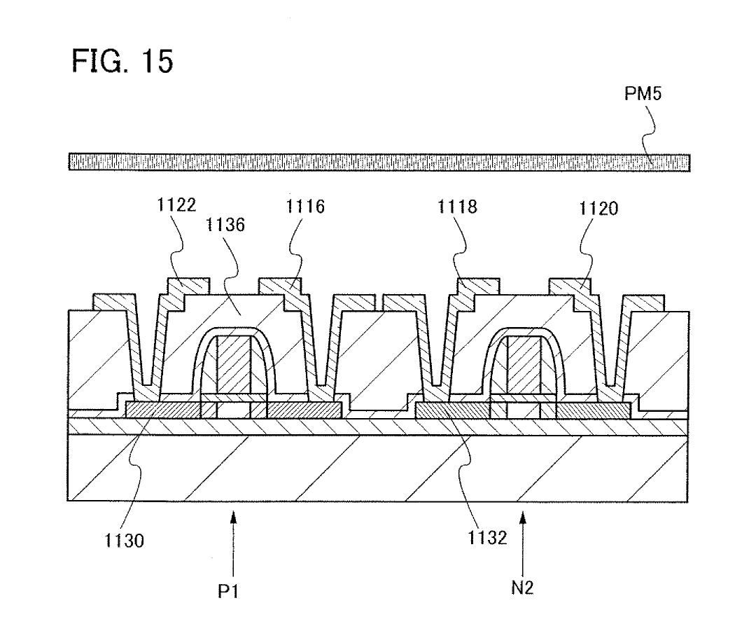

FIG. 15 illustrates a process in which second wiring layers 1116, 1118, 1120, and 1122 are formed. The second wiring layers 1116, 1118, 1120, and 1122 can be formed to have either a single-layer structure or a stacked-layer structure of an element selected from among aluminum, tungsten, titanium, tantalum, molybdenum, nickel, and neodymium, or an alloy containing a plurality of the above elements. For example, as a conductive film which is made of an alloy containing a plurality of the above elements, it is possible to form an aluminum alloy containing titanium, an aluminum alloy containing neodymium, or the like. In the case of forming a stacked-layer structure, a structure where an aluminum layer or the aluminum alloy layer as described above is sandwiched between titanium layers can be employed, for example. The second wiring layer 1116 forms the power supply line (VDD), while the second wiring layer 1118 forms the ground potential line (GND)

With the light exposure apparatus of the present invention, the mask layer with reduced variation in light exposure can be formed. As a result, contact holes with uniform diameters can be formed; in other words, areas of contact portions of the p-type impurity region 1130 and the second wiring layers 1116 and 1122, and those of the n-type impurity region 1132 and the second wiring layers 1118 and 1120 can be almost equalized. Consequently, variation in electrical properties due to variation in diameters of the contact holes can be suppressed, which is favorable.

Embodiment Mode 1 has given the p-channel transistor Pt and the n-channel transistor N2, which are included in the circuit array shown in FIG. 11, as an example and explained the making process thereof. Other transistors can be formed in the same manner. This embodiment mode has described an example of using the light exposure apparatus of the present invention for forming gate electrodes and contact holes. Even when a light exposure process with the light exposure apparatus of the present invention is employed for forming only either gate electrodes or contact holes, the light exposure process with the light exposure apparatus of the present invention is effective as well in that variation in light exposure can be reduced in forming a mask. Furthermore, the light exposure apparatus of the present invention can also be used in a light exposure process required for forming a semiconductor layer or a wiring layer.

### Embodiment Mode 2

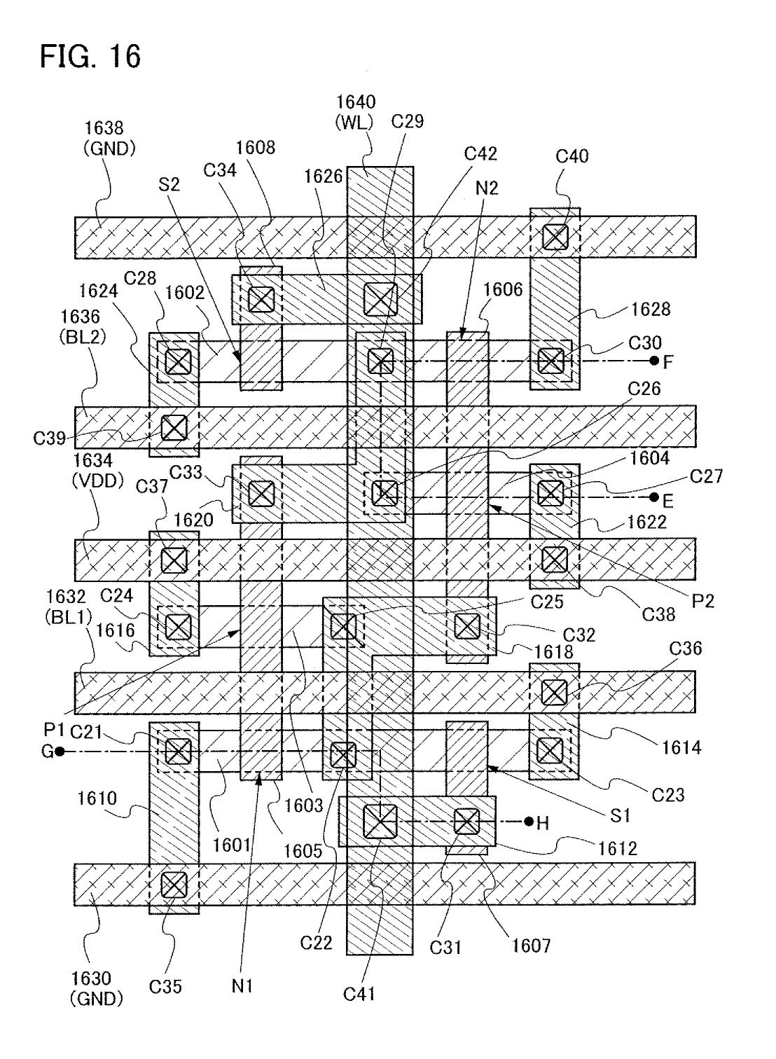

FIG. 16 shows another example of a circuit array of the SRAM shown in FIG. 10. FIG. 16 shows an SRAM having a semiconductor layer, a gate electrode layer, and three wiring layers. The SRAM includes semiconductor layers 1601 and 1602 for forming n-channel transistors, and semiconductor layers 1603 and 1604 for forming p-channel transistors. Further, gate electrode layers 1605, 1606, 1607, and 1608 functioning as gate wiring layers are provided over the semiconductor layers 1601, 1602, 1603, and 1604 with an insulating layer interposed therebetween. The n-channel transistors N1 and N2, the p-channel transistors P1 and P2, and the switches S1 and S2 are formed of these layers.

First wiring layers 1610, 1612, 1614, 1616, 1618, 1620, 1622, 1624, 1626, and 1628, which are in contact with the gate electrode layers, are provided over a first interlayer insulating layer Second wiring layers 1632 and 1636 for forming bit lines and second wiring layers 1630 and 1638 for forming ground potential lines are provided over a second interlayer insulating layer. Further, a third wiring layer 1640 for forming a word line is provided over a third interlayer insulating layer.

The first wiring layers and the semiconductor layers are connected to each other through contact holes C21 to C30, which are provided in the first interlayer insulating layer. The second wiring layers and the first wiring layers are connected to each other through contact holes C31 to C40, which are provided in the second interlayer insulating layer. The third wiring layers and the first wiring layers are connected to each other through contact holes C41 and C42, which are provided in the first interlayer insulating layer and the second interlayer insulating layer. The SRAM shown in FIG. 10 is formed with these contacts.

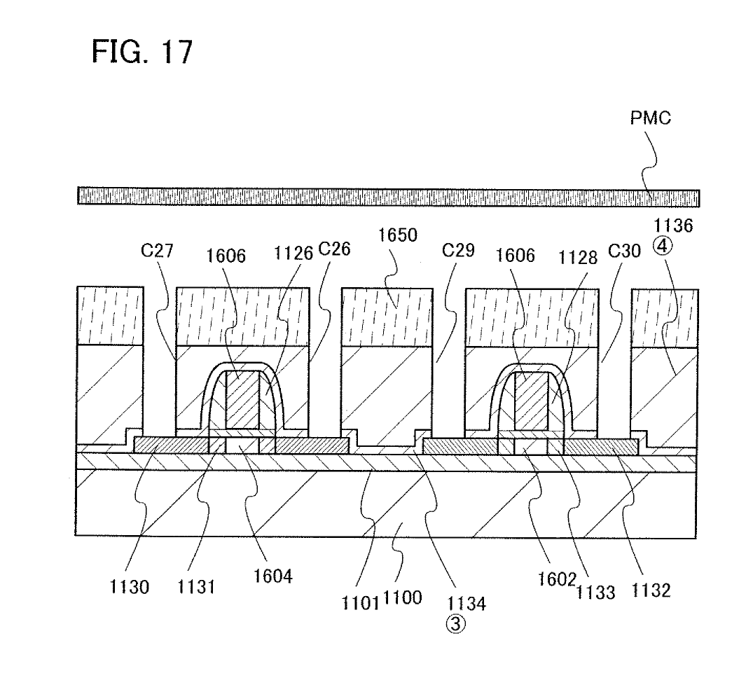

Next, a process of making such an SRAM is explained with reference to FIG. 17, which is a cross-sectional view taken along a line E-F (the p-channel transistor P2 and the n-channel transistor N2) of FIG. 16.

In FIG. 17, a first insulating layer 1101, semiconductor layers 1602 and 1604, a second insulating layer 1103, a gate electrode layer 1606, side spacers 1126 and 1128, a third insulating layer 1134, and a fourth insulating layer 1136, which are provided over the substrate 1100 are formed in a similar way to Embodiment Mode 1.

The contact holes C26, C27, C29, and C30, which penetrate the third insulating layer 1134 and the fourth insulating layer 1136 to expose the n-type impurity region 1132 and the p-type impurity region 1130, are formed by an etching process using a mask layer 1650. The mask layer 1650 is formed by a light exposure process at this time, light exposure is performed with the use of a photomask and the light exposure apparatus explained with reference to FIG. 1, so that the mask layer 1650 having contact holes and with reduced variation in light exposure can be formed. The third insulating layer 1134 and the fourth insulating layer 1136 are etched using the mask layer 1650, so that the contact holes C4, C5, C7, and C8 can be formed.

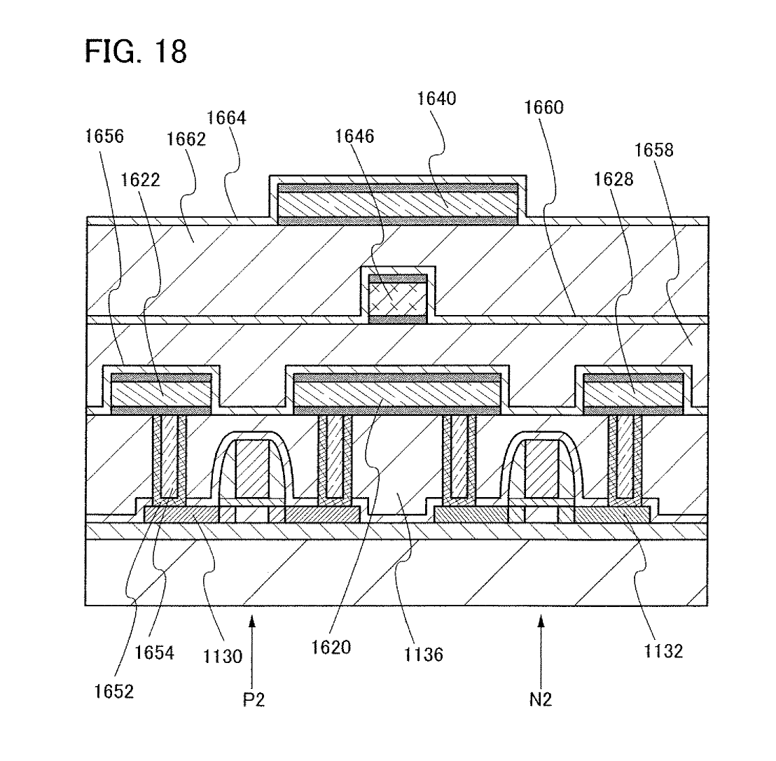

FIG. 18 shows a structure in which embedded conductive layers 1654 are formed in the contact holes C26, C27, C29, and C30, and first wiring layers 1620, 1622, and 1628 are formed. As the embedded conductive layers 1654, tungsten can be typically used. It is preferable that a titanium nitride film, or a titanium film and a titanium nitride film be formed as an adhesive layer 1652, upon which a tungsten film is formed as the embedded conductive layer 1654 in the contact holes C26, C27, C29, and C30. The tungsten film is formed by reducing a WF₆ gas with hydrogen or disilane. Alternatively, the tungsten film may be formed by a sputtering method. After that, the tungsten film is flattened by etching back with a SF₆ gas or by chemical mechanical polishing, thereby forming the embedded conductive layers 1654. After that, the first wiring layers 1620, 1622, and 1628 are formed to be in contact with the respective embedded conductive layers 1654.

A fifth insulating layer 1656 is formed for passivation over the first wiring layers 1620, 1622, and 1628, using a silicon nitride film or the like. A sixth insulating layer 1658 is formed by a vapor deposition method such as plasma CVD or thermal CVD, or by a sputtering method, using silicon oxide, silicon oxynitride (SiOₓN_{y}) (x>y>0), silicon nitride oxide (SiNₓO_{y}) (x>y>0), or the like. Alternatively, the sixth insulating layer 1658 can be formed to have a single-layer structure or a stacked-layer structure of an organic material such as polyimide, polyamide, polyvinyl phenol, benzocyclobutene, acrylic, or epoxy; a siloxane material such as a siloxane resin; oxazole resin; or/and the like. It is preferable that such resin materials be a thermal-curing type or a photo-curing type, and be formed by a spin coating method. By applying a spin coating method, asperity of the wiring layers under the sixth insulating layer 1658 can be reduced, and thus the surface of the sixth insulating layer 1658 can be flattened.

After that, the second wiring layer 1636, a seventh insulating layer 1660 serving for passivation, an eighth insulating layer 1662 for flattening, and the third wiring layer 1640 are formed in a similar way. It is also possible to form the contact holes C31 to C40, through which the second wiring layers and the first wiring layers are connected, and the contact holes C41 and C42, through which the third wiring layers and the first wiring layers are connected, in FIG. 16, by the light exposure process, using the light exposure apparatus of the present invention.

Embodiment Mode 2 has given the p-channel transistor P2 and the n-channel transistor N2, which are included in the circuit array shown in FIG. 16, as an example and explained the making process thereof. Other transistors can be formed in the same manner. This embodiment mode has described an example of using the light exposure apparatus of the present invention for forming gate electrodes and contact holes. Even when a light exposure process with the light exposure apparatus of the present invention is employed for forming only either gate electrodes or contact holes, the light exposure process with the light exposure apparatus of the present invention is effective as well in that variation in light exposure can be reduced in forming a mask. Furthermore, the light exposure apparatus of the present invention can also be used in a light exposure process required for forming a semiconductor layer or a wiring layer.

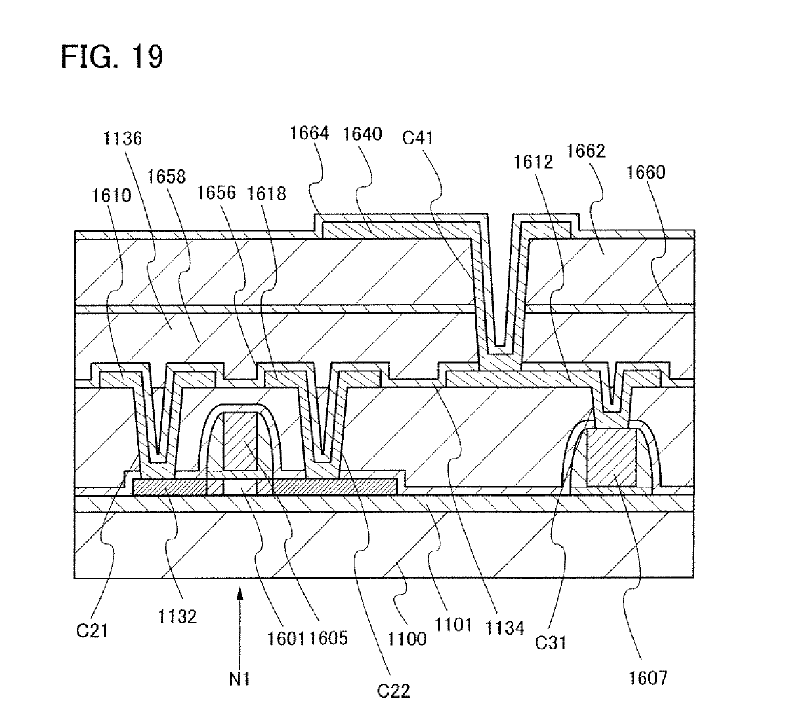

FIG. 19 shows an example of filling contact holes with a material for forming an insulating layer without forming the embedded conductive layers. A cross-sectional view shown in FIG. 19 is taken along a line G-H of FIG. 16.

In FIG. 19, the n-channel transistor N1 has a similar structure to the n-channel transistor N2 shown in FIG. 18. The contact holes C21, C22, and C31, which penetrate the third insulating layer 1134 and the fourth insulating layer 1136 to expose the n-type impurity region 1132 and the first wiring layer 1610, can be formed by forming the mask layer using the light exposure apparatus of the present invention and performing etching in the similar manner to that shown in FIG. 17.

The first wiring layers 1610, 1612, and 1618 can be formed to have either a single-layer structure or a stacked-layer structure of an element selected from among aluminum, tungsten, titanium, tantalum, molybdenum, nickel and neodymium, and an alloy containing a plurality of the above elements. For example, as a conductive film which is made of an alloy containing a plurality of the above elements, it is possible to form an aluminum alloy containing titanium, an aluminum alloy containing silicon, or the like. The first wiring layer 1610 connects the n-channel transistor N1 and the second wiring layer 1630, which is a ground potential line (GND). The first wiring layer 1618 connects the n-channel transistor N1 and a drain of the p-channel transistor P1. The first wiring layer 1612 connects the gate electrode layer 1607 of the switch S1 and the third wiring layer 1640, which is a word line.

The contact hole C41 for connecting the first wiring layer 1612 and the third wiring layer 1640 penetrates the fifth insulating layer 1656, the sixth insulating layer 1658, the seventh insulating layer 1660, and the eighth insulating layer 1662. Such a deep contact hole can also be formed using the light exposure apparatus of the present invention. Although FIG. 19 shows the n-channel transistor N1, other transistors shown in FIG. 16 can be formed in a similar way.

### Embodiment Mode 3

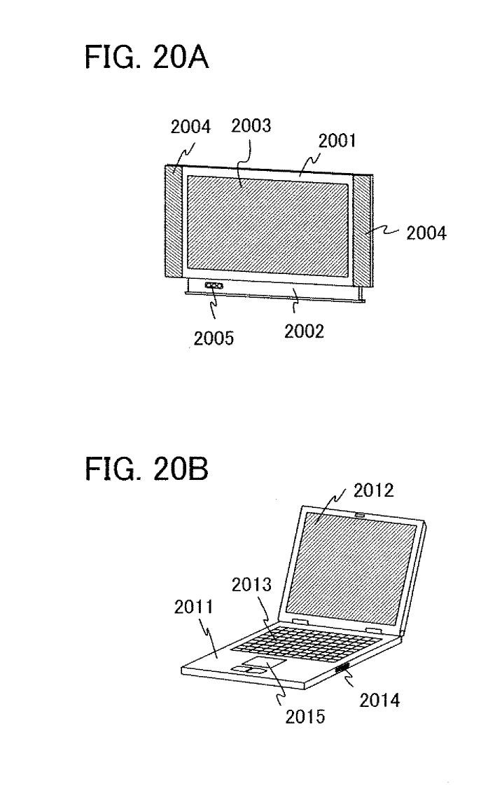

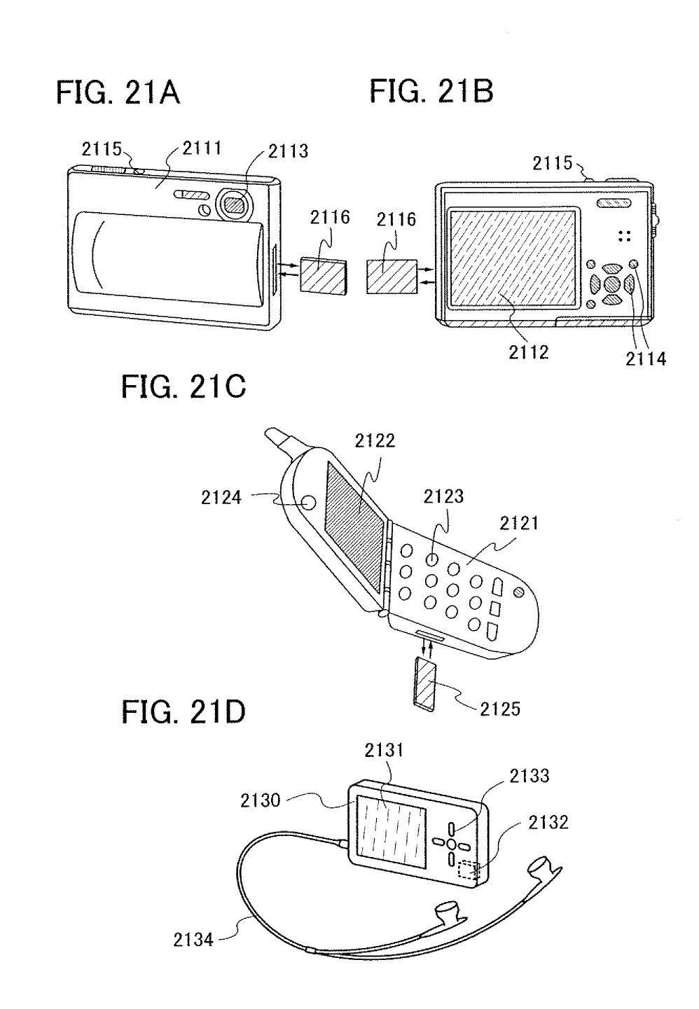

Various electronic appliances can be made using the semiconductor device formed using the present invention. Specific examples are explained with reference to FIGS. 20A to 21D.

According to the present invention, variation in light exposure on a resist formed over a semiconductor film can be reduced in a light exposure process of a process of making a semiconductor device. Reducing the variation in light exposure facilitates accurate formation of a wiring or the like. Therefore, the quality of products including the semiconductor elements is favorable and the product quality can be evened up. As a result, electronic appliances as end products can be made with high throughput and high quality. Specific examples are explained with reference to the drawings.

FIG. 20A shows a display device including a housing 2001, a supporter 2002, a display portion 2003, a speaker portion 2004, a video input terminal 2005, and the like. This display device is made using the transistor formed by the making method shown in the other embodiment modes for a driver IC, the display portion 2003, and the like. The display device includes a liquid crystal display device, a light-emitting display device, and the like; and all the information displaying devices for computers, television reception, advertisement display, and so on. Specifically, examples of the display device include a display, a head mount display, a reflection-type projector, and the like.

FIG. 20B shows a computer including a housing 2011, a display portion 2012, a keyboard 2013, an external connection port 2014, a pointing mouse 2015, and the like. A transistor formed according to the present invention can be applied not only to a pixel portion in the display portion 2012 but also to a semiconductor device such as a driver IC for display, a CPU inside a main body, or a memory.

FIGS. 21 A and B show a digital camera. FIG. 21B shows the reverse side of the digital camera shown in FIG. 21A, This digital camera includes a housing 2111, a display portion 2112, a lens 2113, operation keys 2114, a shutter 2115, and the like. Further, the digital camera includes a removable memory 2116, in which data taken with the digital camera is stored. The transistor formed according to the present invention can be applied to a pixel portion in the display portion 2112, the memory 2116, a driver IC for driving the display portion 2112, and the like.

FIG. 21C shows a cellular phone, which is a typical example of mobile information processing terminals. This cellular phone includes a housing 2121, a display portion 2122, operation keys 2123, and the like. Further, the cellular phone includes a removable non-volatile memory 2125, and data such as phone numbers, images, and music in the cellular phone can be stored in the memory 2125 and reproduced. A transistor formed according to the present invention can be applied not only to a pixel portion in the display portion 2122, the sensor portion 2124, or the memory 2125, but also to a driver IC for display, a memory, an audio processing circuit, and the like. The sensor portion 2124 includes an optical sensor element, by which the brightness of the display portion 2122 is controlled according to the illuminance of the sensor portion 2124, and by which the illumination brightness of the operation key 2123 is controlled according to the illuminance of the sensor portion 2124. Thus, the power consumption of the cellular phone can be suppressed.

In addition to the above cellular phone, the semiconductor device formed according to the present invention can be used for electronic appliances such as a personal digital assistant (PDA), a digital camera, or a compact game machine. For example, it is possible to apply the semiconductor device of the present invention to a functional circuit such as a CPU, a memory, or a sensor; a pixel portion of such electronic appliances; or a driver IC for display.

FIG. 21D shows a digital player. This digital player includes a main body 2130, a display portion 2131, a memory portion 2132, an operation portion 2133, a pair of earphones 2134, and the like. Headphones or wireless earphones can be substituted for the earphones 2134. A transistor formed according to the present invention can be applied not only to the display portion 2131 or the memory portion 2132, but also to a driver IC for display, a memory, an audio processing circuit, and the like. A semiconductor memory device provided in the memory portion 2132 may be removable.

In addition, transistors formed according to the present invention can be applied to a video camera, a navigation system, a sound reproducing device, an image reproducing device equipped with a recording medium, and the like: to be specific, the transistors formed according to the present invention can be applied to pixel portions of display portions, driver ICs for controlling the display portions, memories, digital input processing devices, sensor portions, and the like of these devices.

As described, the application range of a semiconductor device made according to the present invention is highly wide, and the semiconductor device made according to the present invention can be applied to electronic appliances of every field. Note that not only glass substrates but also heat-resistant substrates formed with a synthetic resin can be used for forming the display devices used in the electronic appliances according to the size, strength, or intended purpose. Accordingly, further reduction in weight can be achieved.

This application is based on Japanese Patent Application serial no. 2006-275663 filed in Japan Patent office on Oct. 6, 2006, the entire contents of which are hereby incorporated by reference.

What is claimed is:

1. A method for making a semiconductor device:
performing an exposure process by irradiating a pulsed laser light to a resist film over a substrate,
wherein a solid-state laser is used as a laser source of the laser light; and
wherein the laser light has a repetition rate of 1 MHz or higher.

2. A method for making a semiconductor device:
performing an exposure process by irradiating a pulsed laser light to a resist film over a substrate,
wherein a solid-state laser is used as a laser source of the laser light; and
wherein the laser light has a repetition rate of 5 MHz or higher.

3. A method for making a semiconductor device:
performing an exposure process by irradiating a pulsed laser light to a resist film over a substrate,
wherein a solid-state laser is used as a laser source of the laser light; and
wherein the laser light has a repetition rate of 50 MHz or higher.

4. A method for making a semiconductor device:
performing an exposure process by irradiating a pulsed laser light to a resist film over a substrate,
wherein a solid-state laser is used as a laser source of the laser light; and
wherein the laser light has a repetition rate of 80 MHz or higher.

5. A method for making a semiconductor device:
forming a semiconductor layer over a substrate,
forming a gate insulating layer on the semiconductor layer,
forming a wiring on the gate insulating layer, and
performing an exposure process by irradiating a pulsed laser light to a resist film on the wiring using a photo-mask in order to form a gate electrode,
wherein a solid-state laser is used as a laser source of the pulsed laser light; and
wherein the laser light has a repetition rate of 1 MHz or higher.

6. A method for making a semiconductor device according to claim 1, wherein the pulse width of the laser light is 1/100 or smaller one cycle width of the laser light.

7. A method for making a semiconductor device according to claim 2, wherein the pulse width of the laser light is 1/100 or smaller one cycle width of the laser light.

8. A method for making a semiconductor device according to claim 3, wherein the pulse width of the laser tight is 1/100 or smaller one cycle width of the laser light.

9. A method for making a semiconductor device according to claim 4, wherein the pulse width of the laser light is 1/100 or smaller one cycle width of the laser light.

10. A method for making a semiconductor device according to claim 5, wherein the pulse width of the laser light is 1/100 or smaller one cycle width of the laser light.

11. A method for making a semiconductor device according to claim 1, wherein the movement rate is 0.1 μm or smaller every pulse, and the maximum value of a scanning speed is 5 cm/sec or more.

12. A method for making a semiconductor device according to claim 2, wherein the movement rate is 0.1 μm or smaller every pulse, and the maximum value of a scanning speed is 5 cm/sec or more.

13. A method for making a semiconductor device according to claim 3, wherein the movement rate is 0.1 μm or smaller every pulse, and the maximum value of a scanning speed is 5 cm/sec or more.

14. A method for making a semiconductor device according to claim 4, wherein the movement rate is 0.1 μm or smaller every pulse, and the maximum value of a scanning speed is 5 cm/sec or more.

15. A method for making a semiconductor device according to claim 5, wherein the movement rate is 0.1 μm or smaller every pulse, and the maximum value of a scanning speed is 5 cm/sec or more.

16. A method for making a semiconductor device according to claim 1, wherein the overlap percentage of the laser light between pulses is 99.9% or more, and the maximum value of a scanning speed is 5 cm/sec or more.

17. A method for making a semiconductor device according to claim 2, wherein the overlap percentage of the laser light between pulses is 99.9% or more, and the maximum value of a scanning speed is 5 cm/sec or more.

18. A method for making a semiconductor device according to claim 3, wherein the overlap percentage of the laser light between pulses is 99.9% or more, and the maximum value of a scanning speed is 5 cm/sec or more.

19. A method for making a semiconductor device according to claim 4, wherein the overlap percentage of the laser light between pulses is 99.9% or more, and the maximum value of a scanning speed is 5 cm/sec or more.

20. A method for making a semiconductor device according to claim 5, wherein the overlap percentage of the laser light between pulses is 99.9% or more, and the maximum value of a scanning speed is 5 cm/sec or more.

21. A method for making a semiconductor device according to claim 1, wherein the surface is scanned with the laser light as the laser light moves relatively to the surface.

22. A method for making a semiconductor device according to claim 2, wherein the surface is scanned with the laser light as the laser light moves relatively to the surface.

23. A method for making a semiconductor device according to claim 3, wherein the surface is scanned with the laser light as the laser light moves relatively to the surface.

24. A method for making a semiconductor device according to claim 4, wherein the surface is scanned with the laser light as the laser light moves relatively to the surface.

25. A method for making a semiconductor device according to claim 5, wherein the surface is scanned with the laser light as the laser light moves relatively to the surface.

26. A light exposure apparatus for irradiating a laser light to an irradiation surface through a mask comprising:
a laser source in a light exposure process:
wherein a pulsed solid-state laser light is used for the laser source, and
wherein the laser light has a repetition rate of 1 MHz or higher.

27. A light exposure apparatus for irradiating a laser light to an irradiation surface through a mask comprising:
a laser source in a light exposure process:
wherein a pulsed solid-state laser light is used for the laser source; and
wherein the laser light has a repetition rate of 5 MHz or higher.

28. A light exposure apparatus for irradiating a laser light to an irradiation surface through a mask comprising:
a laser source in a light exposure process:
wherein a pulsed solid-state laser light is used for the laser source; and
wherein the laser light has a repetition rate of 50 MHz or higher.

29. A light exposure apparatus for irradiating a laser light to an irradiation surface through a mask comprising
a laser source in a light exposure process;
wherein a puled solid-state laser light is used for the laser source; and
wherein the laser light has a repetition rate of 80 MHz or higher.

30. A light exposure apparatus according to claim 26, wherein the mask is a photomask or a reticle on which a pattern is formed on a transparent substrate by a light-shielding film.

31. A light exposure apparatus according to claim 27, wherein the mask is a photomask or a reticle on which a pattern is formed on a transparent substrate by a light-shielding film.

32. A light exposure apparatus according to claim 28, wherein the mask is a photomask or a reticle on which a pattern is formed on a transparent substrate by a light-shielding film.

33. A light exposure apparatus according to claim 29, wherein the mask is a photomask or a reticle on which a pattern is formed on a transparent substrate by a light-shielding film.

34. A light exposure apparatus according to claim 26, wherein the mask is a hologram or a computer-generated hologram.

35. A light exposure apparatus according to claim 27, wherein the mask is a hologram or a computer-generated hologram.

36. A light exposure apparatus according to claim 28, wherein the mask is a hologram or a computer-generated hologram.

37. A light exposure apparatus according to claim 29, wherein the mask is a hologram or a computer-generated hologram.

38. A light exposure apparatus according to claim 26, wherein the pulse width of the laser light is 1/100 or smaller one cycle width of the laser light.

39. A light exposure apparatus according to claim 27, wherein the pulse width of the laser light is 1/100 or smaller one cycle width of the laser light.

40. A light exposure apparatus according to claim 28, wherein the pulse width of the laser light is 1/100 or smaller one cycle width of the laser light.

41. A light exposure apparatus according to claim 29, wherein the pulse width of the laser light is 1/100 or smaller one cycle width of the laser light.

42. A light exposure apparatus according to claim 26, wherein the surface is scanned with the laser light as the laser light moves relatively to the surface.

43. A light exposure apparatus according to claim 27, wherein the surface is scanned with the laser light as the laser light moves relatively to the surface.

44. A light exposure apparatus according to claim 28, wherein the surface is scanned with the laser light as the laser light moves relatively to the surface.

45. A light exposure apparatus according to claim 29, wherein the surface is scanned with the laser light as the laser light moves relatively to the surface.

46. A light exposure apparatus according to claim 26, wherein the laser light has a linear shape.

47. A light exposure apparatus according to claim 27, wherein the laser light has a linear shape.

48. A light exposure apparatus according to claim 28, wherein the laser light has a linear shape.

49. A light exposure apparatus according to claim 29, wherein the laser light has a linear shape.
